(19) United States
(12) Patent Application Publication
(10) Pub. No.: US 2026/0123294 A1
(43) Pub. Date: Apr. 30, 2026

(54) PHASE CHANGE MATERIAL DEVICE AND METHODS FOR FORMING THE SAME

(71) Applicant: Taiwan Semiconductor Manufacturing Company Limited, Hsinchu (TW)

(72) Inventors: Chang-Chih HUANG, Taichung (TW); Chih-Ren HSIEH, Changhua City (TW); Kuo-Pin CHANG, Zhubei City (TW); Kuo-Ching HUANG, Hsinchu City (TW)

(21) Appl. No.: 19/050,401

(22) Filed: Feb. 11, 2025

Related U.S. Application Data
(60) Provisional application No. 63/711,791, filed on Oct. 25, 2024.

(51) Int. Cl. H10N 70/20; H10B 63/10; H10N 70/00

(52) U.S. Cl. CPC H10N 70/231; H10B 63/10; H10N 70/023; H10N 70/026; H10N 70/063; H10N 70/066; H10N 70/068; H10N 70/841; H10N 70/8613

(57) ABSTRACT

A phase change memory device may be provided by forming a bottom electrode, a dielectric material layer, and a via opening extending through the dielectric material layer such that a top surface segment of the bottom electrode is exposed underneath the via opening; forming a tubular dielectric spacer in a peripheral region of the via opening; depositing a continuous layer stack including a heater liner layer, a phase change material layer comprising a phase change material, and a top electrode material layer over the dielectric material layer and the tubular dielectric spacer; and patterning the continuous layer stack into a layer stack including a heater liner, a phase change material portion, and a top electrode.

### RELATED APPLICATIONS

This application claims the benefit of priority to U.S. Provisional Application No. 63/711,791 entitled “Phase Change Memory Device and Methods for Manufacturing the Same” filed on Oct. 25, 2024, the entire contents of which are incorporated by reference herein for all purposes.

### BACKGROUND

Phase change material (PCM) devices may be used for memory-based computing applications due to their scalability and non-volatility. However, the manufacturing process sequence for PCM devices requires many processing steps. One of the time-consuming and costly processing steps involves formation of bottom electrodes and heater elements using a chemical mechanical polishing process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. The dimensions of the various features may be arbitrarily increased or reduced for clarity of discussion.

FIG. 1 is a vertical cross-sectional view of a first embodiment intermediate structure after formation of field effect transistors, metal interconnect structures, and dielectric material layers according to an embodiment of the present disclosure.

FIG. 2 is a vertical cross-sectional view of the first embodiment intermediate structure after formation of via openings through a dielectric material layer according to an embodiment of the present disclosure.

FIG. 3 is a vertical cross-sectional view of the first embodiment intermediate structure after formation of a dielectric spacer material layer according to an embodiment of the present disclosure.

FIG. 4 is a vertical cross-sectional view of the first embodiment intermediate structure after formation of tubular dielectric spacers according to an embodiment of the present disclosure.

FIG. 5 is a vertical cross-sectional view of the first embodiment intermediate structure after formation of a continuous layer stack including a heater liner layer, a phase change material layer, and a top electrode material layer according to an embodiment of the present disclosure.

FIG. 6 is a vertical cross-sectional view of the first embodiment intermediate structure after patterning the continuous layer stack into in-process layer stacks each including an in-process heater liner, an in-process phase change material portion, and an in-process top electrode according to an embodiment of the present disclosure.

FIG. 7 is a vertical cross-sectional view of the first embodiment intermediate structure after formation of a sidewall liner layer according to an embodiment of the present disclosure.

FIG. 8 is a vertical cross-sectional view of the first embodiment intermediate structure after formation of in-process sidewall liners according to an embodiment of the present disclosure.

FIG. 9 is a vertical cross-sectional view of the first embodiment intermediate structure after patterning the in-process layer stacks into layer stacks each including a heater liner, a phase change material portion, and a top electrode and patterning the in-process sidewall liners into sidewall liners according to an embodiment of the present disclosure.

FIG. 10 is a vertical cross-sectional view of the first embodiment structure after removal of a patterned etch mask layer according to an embodiment of the present disclosure.

FIGS. 11A-11C illustrate sequential top-down views of a region of a first configuration of the first embodiment structure during the processing steps of FIGS. 8-10.

FIGS. 12A-12C illustrate sequential top-down views of a region of a second configuration of the embodiment structure during the processing steps of FIGS. 8-10.

FIGS. 13A-13C illustrate sequential top-down views of a region of a third configuration of the embodiment structure during the processing steps of FIGS. 8-10.

FIG. 14 illustrates a top-down view of a region of a fourth configuration of the embodiment structure after the processing steps of FIG. 8.

FIG. 15 is a vertical cross-sectional view of the first embodiment structure after formation of an encapsulation dielectric layer and additional metal interconnect structures according to an embodiment of the present disclosure.

FIGS. 16A-16D are various configurations of a phase change memory cell in various programmed resistance states according to an embodiment of the present disclosure.

FIG. 17 is a vertical cross-sectional view of a second embodiment intermediate structure after deposition of a heater liner layer according to an embodiment of the present disclosure.

FIG. 18 is a vertical cross-sectional view of the second embodiment intermediate structure after vertically recessing the heater liner layer according to an embodiment of the present disclosure.

FIG. 19 is a vertical cross-sectional view of the second embodiment intermediate structure after deposition of a phase change material layer and a top electrode material layer according to an embodiment of the present disclosure.

FIG. 20 is a vertical cross-sectional view of the second embodiment intermediate structure after formation of in-process layer stacks each including an in-process heater liner, an in-process phase change material portion, and an in-process top electrode according to an embodiment of the present disclosure.

FIG. 21 is a vertical cross-sectional view of the second embodiment structure after formation of the encapsulation dielectric layer and the additional metal interconnect structures according to an embodiment of the present disclosure.

FIG. 22 is a vertical cross-sectional view of a third embodiment intermediate structure after deposition of a heater liner layer according to an embodiment of the present disclosure.

FIG. 23 is a vertical cross-sectional view of the third embodiment intermediate structure after deposition of a phase change material layer and a top electrode material layer according to an embodiment of the present disclosure.

FIG. 24 is a vertical cross-sectional view of the third embodiment intermediate structure after formation of in-process layer stacks each including an in-process heater liner, an in-process phase change material portion, and an in-process top electrode according to an embodiment of the present disclosure.

FIG. 25 is a vertical cross-sectional view of the third embodiment structure after formation of the encapsulation dielectric layer and the additional metal interconnect structures according to an embodiment of the present disclosure.

FIG. 26 is a first flowchart that illustrates general processing steps for manufacturing a device structure according to embodiments of the present disclosure.

FIG. 27 is a second flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Phase change memory (PCM) devices may be used in various applications due to their scalability and non-volatility. However, the complexity of the manufacturing process for PCM devices may pose challenges. For example, manufacture of heater elements is typically effected using a chemical mechanical polishing (CMP) process. The CMP process not only requires expensive equipment and consumables but also demands stringent process controls, which may lead to increased production time and/or yield loss.

Various embodiments of the present disclosure provide sequences of manufacturing steps for fabricating phase change memory (PCM) devices while reducing the complexity and processing cost. Specifically, the disclosed sequences of manufacturing steps provide methods for manufacturing PCM devices without using a CMP process. Specifically, a heater liner contacting a bottom surface of a phase change material portion is used to provide a dual function of a heater element and a heater liner for the phase change material portion. The heater liner may be formed by providing a narrow via opening in a dielectric material layer, by filling the entirety or a peripheral region of the via opening with a heater liner layer, and by subsequently patterning the heater liner layer. A phase change material layer and a top electrode material layer may be deposited over the heater material layer, and the heater liner layer, the phase change material layer, and the top electrode material layer may be patterned using a same masking pattern. The heater liner includes a vertically-extending portion that is formed in the via opening, and a horizontally-extending portion that overlies the dielectric material layer. A sidewall liner may be formed on each layer stack of a heater liner, a phase change material portion and a top electrode to provide a phase change memory cell. Thus, the phase change memory cell may be manufactured without using a costly CMP process.

A tubular dielectric spacer may be formed in the via opening prior to formation of the heater liner. In one embodiment, a void in the tubular dielectric spacer may be narrow enough to be completely filled during deposition of the heater liner layer. In another embodiment, the void in the tubular dielectric spacer may be wider than twice the target thickness of a horizontally-extending portion of a heater liner to be subsequently formed, and a combination of an over-deposition and a recess etch may be used to provide the target thickness for the horizontally-extending portion of the heater liner while filling the void in the via opening. In yet another embodiment, the void in the tubular dielectric spacer may be wider than twice the target thickness of a heater liner, and a remaining portion of the void may be filled with a vertically-extending portion of the phase change material portion. The various embodiments of the present disclosure are now described with reference to accompanying drawings.

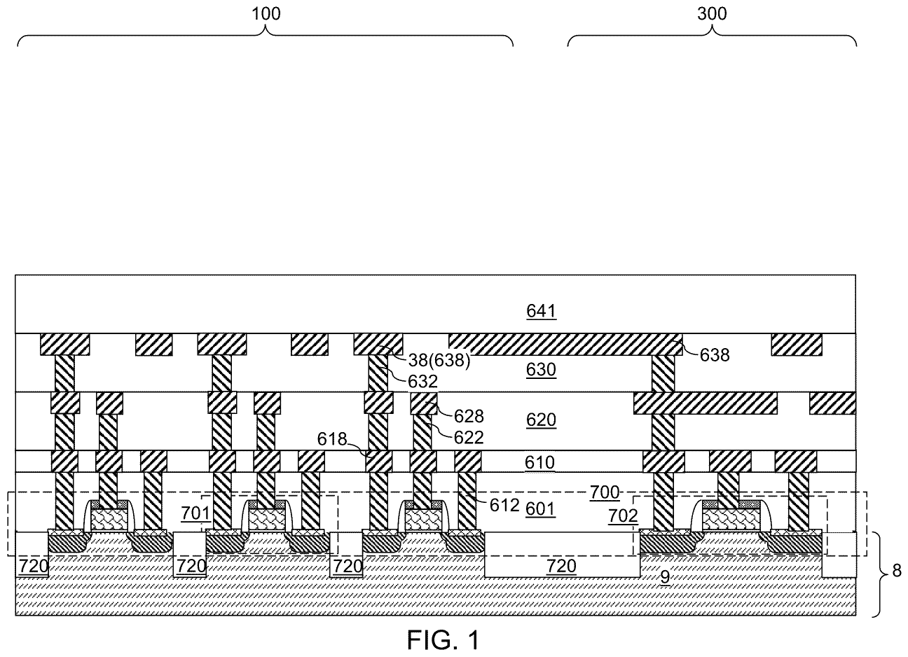

Referring to FIG. 1, a first embodiment structure according to the present disclosure is illustrated. The first embodiment structure includes a substrate 8, which may be a semiconductor substrate, such as a commercially available silicon substrate. The substrate 8 may include a semiconductor material layer 9 at least in an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720.

Semiconductor devices 700 may be formed on the semiconductor material layer 9. The semiconductor devices 700 may comprise complementary metal-oxide-semiconductor (CMOS) transistors and optionally additional semiconductor devices (such as resistors, diodes, capacitor structures, etc.). The semiconductor devices 700 may comprise programming transistors 701 that are formed in a memory array region 100, and peripheral transistors 702 that are formed in a peripheral region 300. Each field effect transistor (701, 702) may comprise a source region, a drain region, a channel region, a gate dielectric, and a gate electrode. In one embodiment, the channel region may comprise a portion of the semiconductor material layer 9, and may comprise a single crystalline semiconductor material. Each of the programming transistors 701 may be configured to provide a set of programming pulses for a respective phase change memory cell to be subsequently formed. The peripheral transistors 702 may be formed as components of a peripheral circuit that controls the operation of the programing transistors 701, and interfaces with an input/output (I/O) circuit (not illustrated).

In one embodiment, the substrate 8 may include a single crystalline silicon substrate, and the field effect transistors (701, 702) may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

Various metal interconnect structures may be formed within dielectric material layers may be subsequently formed over the substrate 8 and the semiconductor devices. In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the semiconductor devices 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, and third metal line structures 638 formed in an upper portion of the third interconnect-level dielectric material layer 630. An additional dielectric material layer, which is herein referred to as a lower fourth interconnect-level dielectric material layer 641 may be formed over the third interconnect-level dielectric material layer 630.

Each of the dielectric material layers (601, 610, 620, 630, 641) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. In one embodiment, the first metal via structures 622 and the second metal line structures 628 may be formed as integrated line and via structures by a dual damascene process. Generally, any contiguous set of a metal line structure (628, 638) and at least one underlying metal via structure (622, 632) may be formed as an integrated line and via structure.

Generally, semiconductor devices (such as field effect transistors (701, 702)) may be formed on a substrate 8, and metal interconnect structures (612, 618, 622, 628, 632, 638) and dielectric material layers (601, 610, 620, 630, 641) over the semiconductor devices. The metal interconnect structures (612, 618, 622, 628, 632, 638) may be formed in the dielectric material layers (601, 610, 620, 630, 641), and may be electrically connected to the semiconductor devices.

A subset of the metal interconnect structures (612, 618, 622, 628, 632, 638) located within a dielectric material layer that underlies a topmost dielectric layer may comprise bottom electrodes 38 (formed as a portion of metal interconnect structure 638) of phase change memory cells to be subsequently formed. In an illustrative example, a subset of the third metal line structures 638 may comprise a two-dimensional array of bottom electrodes 38 for the array of phase change memory cells to be subsequently formed. The bottom electrodes 38 may be formed within a dielectric material layer (such as a third interconnect-level dielectric material layer 630) that underlies a topmost dielectric material layer (such as a lower fourth interconnect-level dielectric material layer 641). The bottom electrodes 38 comprise at least one metal having high electrical conductivity. For example, the bottom electrodes 38 may comprise a metal portion containing copper, aluminum, or tungsten. Optionally, the bottom electrodes 38 may comprise a metallic barrier liner including a metallic barrier material such as TiN, TaN, WN, and/or MoN.

In summary, programming transistors 701 may be formed on a substrate 8. Metal interconnect structures (612, 618, 622, 628, 632, 638) formed within interconnect-level dielectric material layers (601, 610, 620, 630, 641) may be formed over the programming transistors 701. The metal interconnect structures (612, 618, 622, 628, 632, 638) may be configured to be electrically connected to heater elements of phase change memory cells to be subsequently formed.

According to an aspect of the present disclosure, the programming transistors 701 may be configured to program a respective one of the phase change memory cells into at least two different resistive states, and preferably into at least three different resistive states, and more preferably into at least four different resistive states. The programming of each phase change memory cell into different resistive states may be effected by selecting a pulse pattern from a set of pre-programmed pulse patterns that each programming transistor 701 may apply. The pulse patterns may differ from one another by the duration of a pulse pattern and the peak voltage of the pulse pattern. In one embodiment, the total number of resistive states that a phase change memory cell may be programmed into may be in a range from 2 to 64, such as from 3 to 16, and/or from 4 to 8, although a greater number of resistive states may be programmed as needed by altering the pulse pattern that is generated from each programming transistor 701.

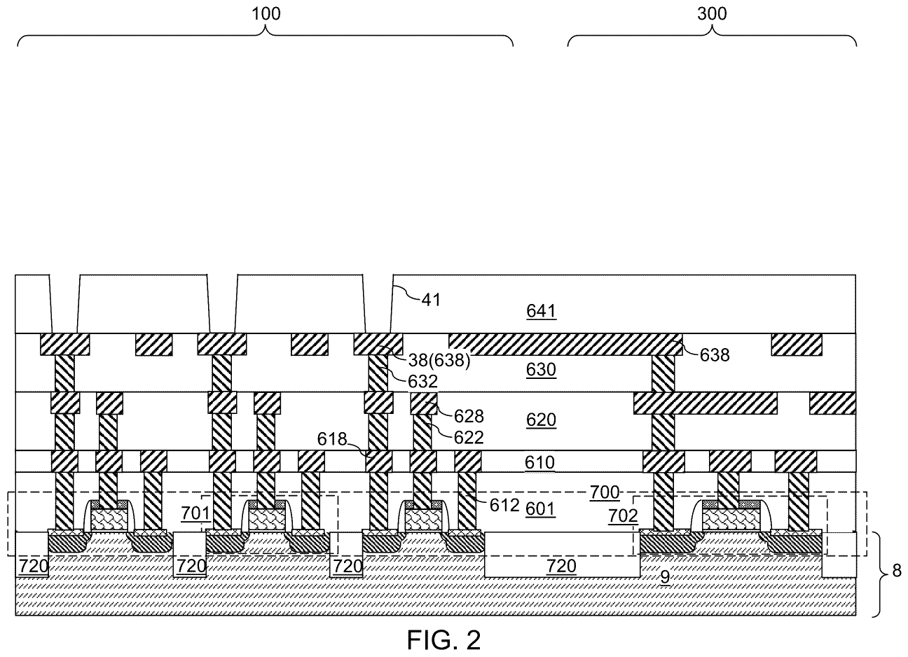

Referring to FIG. 2, via openings 41 may be formed through the topmost dielectric material layer (such as the lower fourth interconnect-level dielectric material layer 641). Each via opening 41 may be formed over a respective one of the underlying metal interconnect structures (such as a subset of the third metal line structures 638) so that top surface segments of the underlying metal interconnect structures are physically exposed. The dielectric material layer, through which the via openings 41 are formed, comprises a heat-resistant dielectric material such as undoped silicate glass or a doped silicate glass. The thickness of the dielectric material layer may be in a range from 200 nm to 1,000 nm, although lesser or greater thicknesses may also be used. The lateral dimension (such as the diameter) of the bottom portion of each via opening 41 may be in a range from 50 nm to 400 nm, although lesser or greater lateral dimensions may also be used.

Generally, bottom electrodes 38, a dielectric material layer (such as the lower fourth interconnect-level dielectric material layer 641), and via openings 41 extending through the dielectric material layer may be formed such that a top surface segment of a respective bottom electrode 38 is exposed underneath each via opening 41.

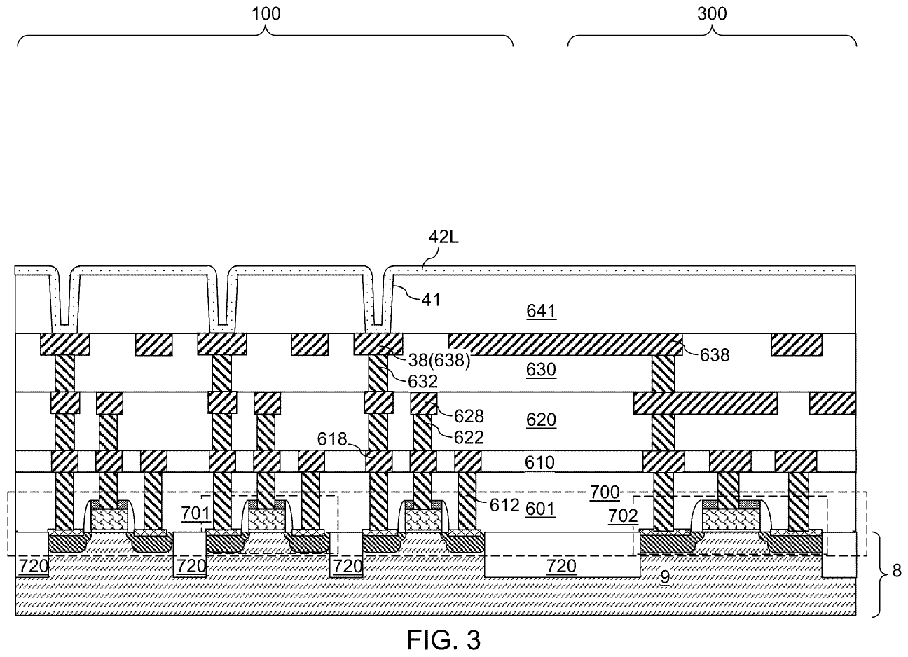

Referring to FIG. 3, a dielectric spacer material may be conformally deposited in peripheral regions of the via openings 41 and over the dielectric material layer (such as the lower fourth interconnect-level dielectric material layer 641) that surrounds the via openings 41, and forms a dielectric spacer material layer 42L. The dielectric spacer material of the dielectric spacer material layer 42L may have a thermal conductivity less than 40 W/m·K. For example, the dielectric spacer material layer 42L may comprise silicon oxide, silicon nitride, aluminum oxide, silicon carbide nitride, or a combination thereof. In one embodiment, the dielectric spacer material of the dielectric spacer material layer 42L may consist essentially of silicon oxide, which has thermal conductivity in a range from 1.1 W/m·K to 1.4 W/m·K. Generally, the dielectric spacer material layer 42L may have the same material composition as, or may have a material composition that is different from, the material composition of the dielectric material layer through which the via openings 41 vertically extend. The dielectric spacer material layer 42L may be deposited by a conformal deposition process such as a chemical vapor deposition process. The top surface of the dielectric spacer material layer 42L may comprise annular convex surface segments that are formed around top peripheries of the via openings 41 due to the isotropic nature of the deposition process that forms the dielectric spacer material layer 42L.

According to an aspect of the present disclosure, the thickness of the dielectric spacer material layer 42L is selected such that the difference between the width of the bottom portion of each via opening 41 and twice the thickness of the dielectric spacer material layer 42L is within a target range for the width of the bottom portion of each vertically-extending portion of a heater liner layer to be subsequently formed. In an illustrative example, in instances in which the width of the bottom portion of each via opening 41 is in a range from 50 nm to 400 nm and if the target range for the width of the bottom portion of each vertically-extending portion of a heater liner layer to be subsequently formed is in a range from 20 nm to 100 nm, the thickness of the dielectric spacer material layer 42L may be in a range from 15 nm to 150 nm, such as from 30 nm to 80 nm, although lesser or greater thicknesses may also be used.

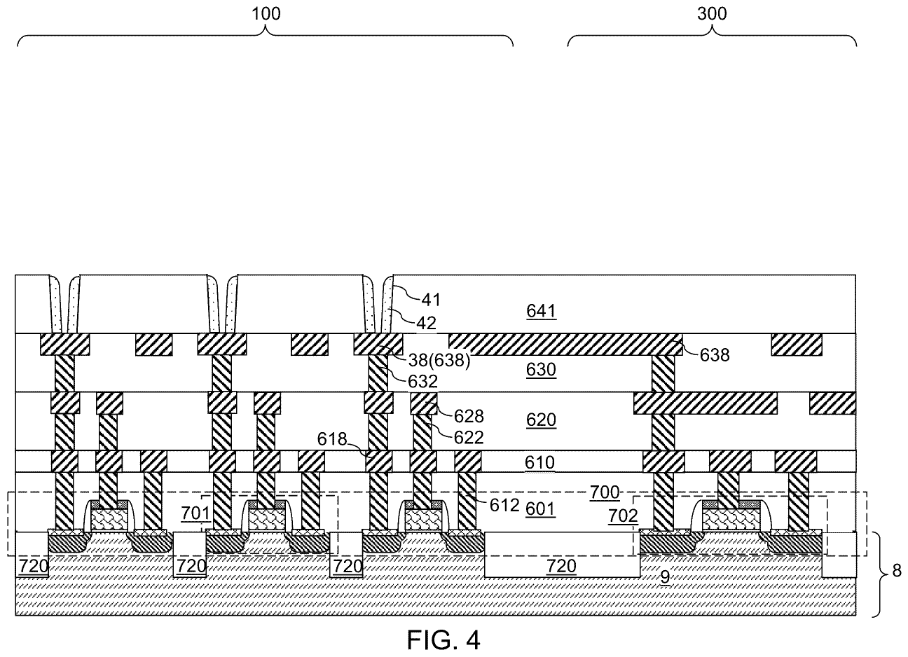

Referring to FIG. 4, an anisotropic etch process may be performed to anisotropically etch horizontally-extending portions of the dielectric spacer material layer 42L. Each remaining vertically-extending portion of the dielectric spacer material layer 42L that remains in a peripheral region of a respective via opening 41 constitutes a tubular dielectric spacer 42 having a tubular configuration. According to an aspect of the present disclosure, a central portion of the top surface segment of an underlying bottom electrode 38 may be exposed under each void that is laterally surrounded by a respective tubular dielectric spacer 42.

Each tubular dielectric spacer 42 may comprise an outer cylindrical sidewall having an outer taper angle in a range from 0 degree to 15 degrees, such as from 1 degree to 5 degrees, with respect to the vertical direction. As used herein, a “cylindrical sidewall” refers to any sidewall that has a closed periphery in a horizontal cross-sectional view and vertically extends with, or without, a taper angle with respect to a vertical direction. Each tubular dielectric spacer 42 may comprise an inner cylindrical sidewall having an inner taper angle in a range from 0 degree to 15 degrees, such as from 1 degree to 5 degrees, with respect to the vertical direction. The inner taper angle may be the same as, or about the same as, the outer taper angle. In one embodiment, each tubular dielectric spacer 42 comprise an annular convex surface segment that is adjoined to a top periphery of the inner cylindrical sidewall of the via openings 41.

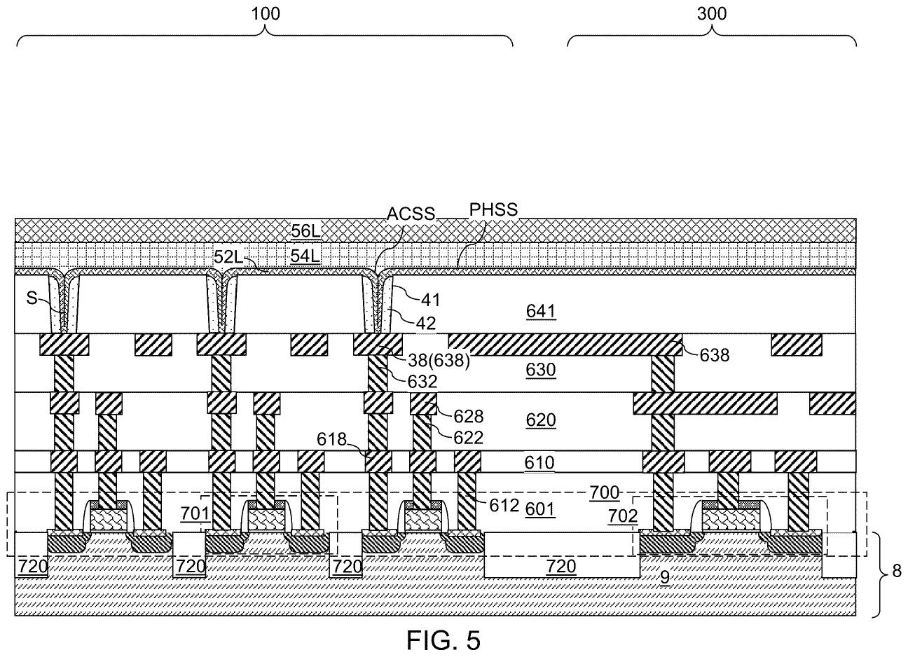

Referring to FIG. 5, a metallic heater material may be deposited in the voids laterally surrounded by the tubular dielectric spacers 42 and over the dielectric material layer (such as the lower fourth interconnect-level dielectric material layer 641) through which the via openings 41 vertically extend. The deposited metallic heater material forms a heater liner layer 52L, which is a liner layer including the metallic heater material. The metallic heater material has a higher electrical conductivity than the metallic material of the bottom electrodes 38. In one embodiment, the heater liner layer 52L comprises a first metallic nitride material, which may be a stoichiometric or near-stoichiometric metallic nitride material. For example, the heater liner layer 52L may comprise TaN, TiN, WN, and/or MoN. In one embodiment, the electrical conductivity of the metallic material of the heater liner layer 52L may be in a range from 1.0×10³ S/cm to 1.0×10⁵ S/cm. The metallic heater material may be deposited by chemical vapor deposition or physical vapor deposition. In one embodiment, the metallic heater material may comprise a stoichiometric or near-stoichiometric metallic nitride material, such as stoichiometric or near-stoichiometric TiN, TaN, WN, and/or MoN.

In one embodiment, a conformal deposition process such as a chemical vapor deposition process may be used to deposit the metallic heater material of the heater liner layer 52L. According to an aspect of the present disclosure, duration of the deposition process that deposits the heater liner layer 52L may be selected such that a predominant fraction, and/or the entirety, of the volume of each void within the via openings 41 is filled with the deposited material of the heater liner layer 52L. The thickness of the horizontally-extending portion of the heater liner layer 52L is selected such that patterned portions of the heater liner layer 52L may provide electrical resistance during operation of phase memory cells to be subsequently formed. The thickness of the horizontally-extending portion of the heater liner layer 52L that is deposited over the top surface of the dielectric material layer through which the via openings 41 vertically extend may be in a range from 10 nm to 80 nm, such as from 20 nm to 50 nm, although lesser or greater thicknesses may also be used.

Generally, the heater liner layer 52L may be deposited within a fraction of the volume of each via opening 41 through a dielectric material layer (such as the lower fourth interconnect-level dielectric material layer 641) and over the horizontal top surface of the dielectric material layer. Upon deposition of the heater liner layer 52L, the heater liner layer 52L comprises a planar horizontal surface segment PHSS that overlies the dielectric material layer and further comprises annular convex surface segments ACSS that are adjoined to the periphery of a respective opening in the planar horizontal surface segment PHSS and overlies a respective one of the via openings 41. Formation of the annular convex surface segments ACSS is due to the isotropic nature of the deposition process that is used to deposit the heater liner layer 52L.

The heater liner layer 52L comprises vertically-extending portions that are deposited in the voids within the tubular dielectric spacers 42 and a horizontally-extending portion that is deposited over the top surface of the dielectric material layer (such as the lower fourth interconnect-level dielectric material layer 641). The heater liner layer 52L at least partially fills each void within the via openings 41. In one embodiment, the maximum width (such as the width at the horizontal plane including the top surface of the dielectric material layer) of each void may be less than one half of the thickness of the heater liner layer 52L as measured at the horizontally-extending portion of the heater liner layer 52L that overlies the dielectric material layer. In one embodiment, a vertically-extending seam S is formed at the center of each void that is filled with a respective vertically-extending portion of the heater liner layer 52L. Each vertically-extending seam S may be formed at a center of a respective vertically-extending portion of the heater liner layer 52L. In one embodiment, the heater liner layer 52L is deposited on each physically exposed central portion of the top surface segments of the bottom electrodes 38.

A phase change material layer 54L may be deposited on the entire physically exposed surfaces of the heater liner layer 52L. Thus, the phase change material layer 54L is deposited directly on the planar horizontal surface segment PHSS of the heater liner layer 52L that overlies a horizontal plane including a top surface of the dielectric material layer (such as the lower fourth interconnect-level dielectric material layer 641), and directly on each annular convex surface segment ACSS of the heater liner layer 52L.

The phase change material layer 54L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and aluminum indium selenium telluride compounds. In one embodiment, the phase change material of the phase change material layer 54L may comprise a doped GST compound such as N-doped GST, Si-doped GST, C-doped GST, Ge-doped GST, Ru-doped GST, or Al-doped GST, or a doped GeTe compound such as N-doped GeTe, Si-doped GeTe, C-doped GeTe, or Ge-doped GeTe. The phase change material layer 54L may be deposited by physical vapor deposition. The thickness of the phase change material layer 54L may be in a range from 30 nm to 200 nm, such as from 50 nm to 90 nm, although lesser or greater thicknesses may also be used. In one embodiment, the phase change material of the phase change material layer may be selected such that the electrical conductivity of the amorphous phase of the phase change material is in a range from 1.0×10⁻⁸ S/cm to 1.0×10⁻³ S/cm, while the electrical conductivity of the crystalline phase of the phase change material is in a range from 1.0×10⁻¹ S/cm to 1.0×10³ S/cm.

The top electrode material layer 56L comprises a metallic material such as W, Ta, Ti, Mo, WN, TiN, WN, or MoN. The top electrode material layer 56L may have a thickness in a range from 100 nm to 200 nm, although lesser or greater thicknesses may also be used. The top electrode material layer 56L may be deposited by chemical vapor deposition or physical vapor deposition.

Generally, a continuous layer stack (52L, 54L, 56L) including a heater liner layer 52L, a phase change material layer 54L comprising a phase change material, and a top electrode material layer 56L may be deposited over the dielectric material layer (such as the lower fourth interconnect-level dielectric material layer 641) and the tubular dielectric spacers 42. The heater liner layer 52L may be deposited directly on the dielectric material layer through which the via openings 41 vertically extend and directly on the tubular dielectric spacers 42 that are located in peripheral regions of the via openings 41.

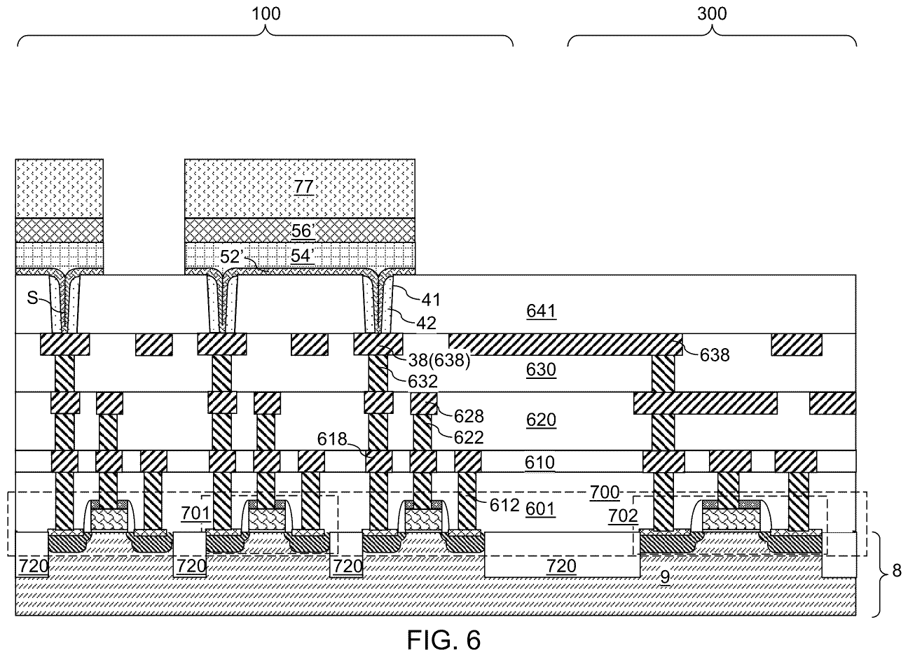

Referring to FIG. 6, a first patterning process may be performed to pattern the continuous layer stack (52L, 54L, 56L) into in-process layer stacks (52′, 54′, 56′). Specifically, a first patterned etch mask layer 77 may be formed over the continuous layer stack (52L, 54L, 56L). For example, the first patterned etch mask layer 77 may be formed by applying a photoresist layer over the continuous layer stack (52L, 54L, 56L), and lithographically patterning the photoresist layer into an array of discrete patterned photoresist material portions. In one embodiment, the first patterned etch mask layer 77 may comprise a two-dimensional array, such as a two-dimensional rectangular periodic array, of patterned photoresist material portions that is located in the memory array region 100. In one embodiment, each patterned photoresist material portion may have a rectangular horizontal cross-sectional shape. In one embodiment, the lateral dimensions of each patterned photoresist material portion may be selected to provide patterning of at least two phase change memory cells in subsequent processing steps. Alternatively, the lateral dimensions of each patterned photoresist material portion may be selected to provide patterning of a single phase change memory cell in subsequent processing steps.

A first anisotropic etch process may be performed to etch portions of the continuous layer stack (52L, 54L, 56L) that are not masked by the first patterned etch mask layer 77. The first anisotropic etch process has an etch chemistry that etches the materials of the continuous layer stack (52L, 54L, 56L) selectively to the material of the dielectric material layer (such as the lower fourth interconnect-level dielectric material layer 641) that embeds the tubular dielectric spacers 42. The continuous layer stack (52L, 54L, 56L) is patterned into in-process layer stacks (52′, 54′, 56′) each including an in-process heater liner 52′, an in-process phase change material portion 54′, and an in-process top electrode 56′. As used herein, an “in-process” element refers to an element that is structurally and/or compositionally modified in a subsequent processing step. Each in-process heater liner 52′ may be a patterned portion of the heater liner layer 52L. Each in-process phase change material portion 54′ may be a patterned portion of the phase change material layer 54L. Each in-process top electrode 56′ may be a patterned portion of the top electrode material layer 56L. For each in-process layer stack (52′, 54′, 56′), the sidewalls of the in-process heater liner 52′ may be vertically coincident with the sidewalls of the in-process phase change material portion 54′, and may be vertically coincident with the sidewalls of the in-process top electrode 56′. As used herein, a first surface is “vertically coincident” with a second surface in which the second surface overlies or underlies the first surface and in which the first surface and the second surface are located within a same vertical plane, which may be planar or curved in a horizontal cross-sectional view. The first patterned etch mask layer 77 may be subsequently removed, for example, by ashing.

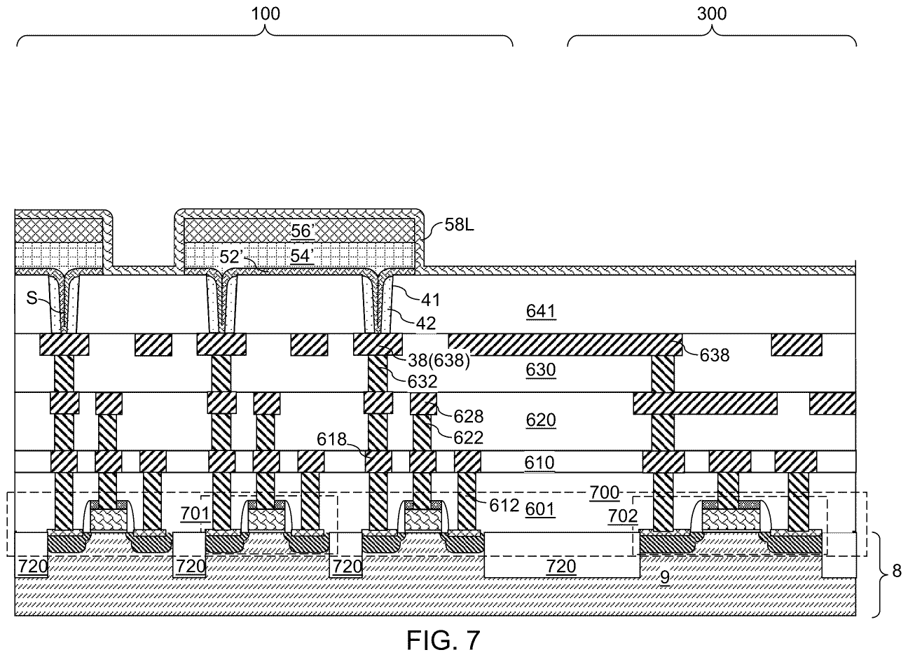

Referring to FIG. 7 and according to an aspect of the present disclosure, a sidewall liner layer 58L may be deposited on the physically exposed surfaces of the in-process layer stacks (52′, 54′, 56′) and on the physically exposed top surface of the dielectric material layer (such as the lower fourth interconnect-level dielectric material layer 641) that embeds the bottom electrodes 38 and the tubular dielectric spacers 42. In one embodiment, the sidewall liner layer 58L may comprise a metallic nitride material layer that is deposited by a conformal deposition process such as a chemical vapor deposition process. In one embodiment, the sidewall liner layer 58L may comprise a second metallic nitride material, which may comprise, and/or may consist essentially of, TiN, TaN, WN, and/or MoN. The thickness of the sidewall liner layer 58L may be in a range from 1 nm to 20 nm, such as from 2 nm to 4 nm, although lesser or greater thicknesses may also be used.

According to an aspect of the present disclosure, the electrical conductivity of the second metallic nitride material may be reduced by incorporating carbon atoms or nitrogen atoms into the metallic nitride material layer by in-situ doping or ex-situ doping of carbon atoms or nitrogen atoms, i.e., incorporation of the carbon atoms or the nitrogen atoms during deposition of the sidewall liner layer 58L or after deposition of the sidewall liner layer 58L. For example, the carbon atoms or the nitrogen atoms may be provided by a reactive carbon-containing gas (such as acetylene or ethylene) or a reactive nitrogen-containing gas (such as ammonia) during a chemical vapor deposition that deposits the sidewall liner layer 58L. Alternatively, the sidewall liner layer 58L may be exposed to an ambient containing reactive carbon-containing species or reactive nitrogen-containing species at an elevated temperature after the deposition process that deposits the sidewall liner layer 58L. Yet alternatively, an ion implantation process or a plasma doping process may be performed after the deposition process that deposits the sidewall liner layer 58L.

The carbon atoms or the nitrogen atoms may be incorporated into the second metallic nitride material of the sidewall liner layer 58L at an atomic concentration such that the electrical conductivity of the doped metallic nitride material of the sidewall liner layer 58L after incorporation of the carbon atoms or the nitrogen atoms is less than ⅓ of the electrical conductivity of the second metallic nitride material prior to the incorporation of the carbon atoms or the nitrogen atoms. In an illustrative example, the electrical conductivity of the sidewall liner layer 58L after incorporation of the carbon atoms or the nitrogen atoms may be in a range from 1.0×10¹ S/cm to 1.0×10⁵ S/cm.

Generally, the ratio of the metal atoms to nitrogen atoms in a stoichiometric metallic compound MN, in which M is Ta, Ti, Mo, or W, is 1:1. In embodiments in which nitrogen doping is used, upon doping of a stoichiometric metallic compound with nitrogen atoms to form the sidewall liner layer 58L of the present disclosure, the ratio of the metal atoms to nitrogen atoms in the sidewall liner layer 58L may be in a range from 1:1.02 to 1:1.05. In embodiments in which carbon doping is used, upon doping of a stoichiometric metallic compound with carbon atoms to form the sidewall liner layer 58L of the present disclosure, the ratio of the metal atoms to nitrogen atoms to carbon atoms in the sidewall liner layer 58L may be in a range from 1:1:0.02 to 1:1:0.05. Generally, the atomic concentration of the extra nitrogen atoms in a nitrogen-doped metallic nitride material may be in a range from 0.02 times the atomic concentration of the metal atoms to 0.05 times the atomic concentration of the metal atoms. Likewise, the atomic concentration of the carbon atoms in a carbon-doped metallic nitride material may be in a range from 0.02 times the atomic concentration of the metal atoms to 0.05 times the atomic concentration of the metal atoms.

In one embodiment, the second metallic nitride material of the sidewall liner layer 58L after the doping process may have an electrical conductivity that is less than ⅓, and preferably less than 1/10, of an electrical conductivity of the first metallic nitride material of the in-process heater liners 52′. In other words, the in-process heater liners 52′ comprise a material having an electrical conductivity that is at least 3 times, and preferably at least 10 times, the electrical conductivity of the sidewall liner material of the sidewall liner layer 58L.

Generally, the first metallic nitride material of the heater liner layer 52L (and of the in-process heater liners 52′) and the second metallic nitride material (which is a doped metallic nitride material) of the sidewall liner layer 58L may be selected such that the resistance of a heater liner to be patterned from an in-process heater liner 52′ and the resistance of a sidewall liner to be patterned from the sidewall liner layer 58L dominate the resistance of states of phase memory material cells having high resistance values, which include the high resistance state and first resistance states having relatively high resistance values. In this embodiment, the resistance of the amorphous volume of a phase change material portion does not determine the resistance of high resistance states of a phase change memory cell. Thus, the phase change memory cell may operate without being affected by any resistance drift of a phase change material.

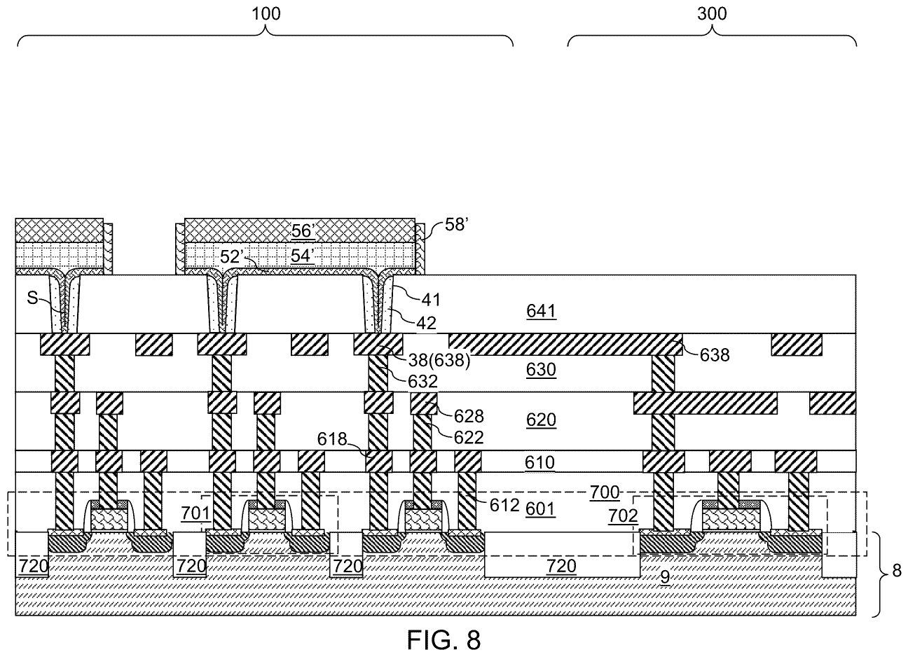

Referring to FIG. 8, an anisotropic etch process may be performed to remove horizontally-extending portions of the sidewall liner layer 58L. The anisotropic etch process may be selective to the material of the dielectric material layer (such as the lower fourth interconnect-level dielectric material layer 641) embedding the tubular dielectric spacers 42. Each remaining vertically-extending portion of the sidewall liner layer 58L constitutes an in-process sidewall liner 58′ that laterally surrounds a respective in-process layer stack (52′, 54′, 56′). Each in-process sidewall liner 58′ contacts each sidewall of the in-process heater liner 52′, the in-process phase change material portion 54′, and the in-process top electrode 56′ of a respective in-process layer stack (52′, 54′, 56′). In one embodiment, an upper surface segment of each sidewall of the in-process top-electrodes 56′ may be physically exposed. Generally, an in-process sidewall liner 58′ may be formed around each in-process layer stack (52′, 54′, 56′) by conformally depositing and anisotropically etching a layer of the sidewall liner material.

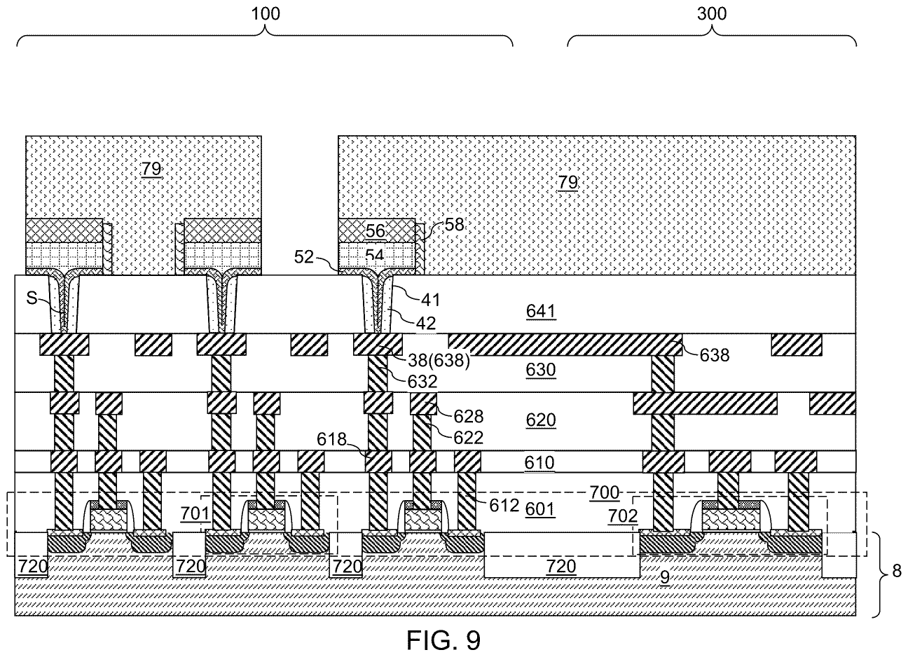

Referring to FIG. 9, a second patterning process may be performed to pattern the in-process layer stacks (52′, 54′, 56′) and the in-process sidewall liners 58′. A second patterned etch mask layer 79 may be formed over the in-process layer stacks (52′, 54′, 56′) and the in-process sidewall liners 58′ in a manner that covers first areas of the in-process layer stacks (52′, 54′, 56′) and the in-process sidewall liners 58′ without covering second areas of the in-process layer stacks (52′, 54′, 56′) and the in-process sidewall liners 58′. For example, a photoresist layer (not shown) may be applied over the in-process layer stacks (52′, 54′, 56′) and the in-process sidewall liners 58′, and may be lithographically patterned into a two-dimensional array, such as a rectangular array, of patterned photoresist material portions. In one embodiment, the second patterned etch mask layer 79 may cover at least two discrete areas of each in-process layer stack (52′, 54′, 56′) that are not interconnected, i.e., that are separated by a gap that is not covered by the second patterned etch mask layer 79.

A second anisotropic etch process may be performed to etch unmasked portions of the in-process layer stacks (52′, 54′, 56′) and the in-process sidewall liners 58′, i.e., to etch the portions of the in-process layer stacks (52′, 54′, 56′) and the in-process sidewall liners 58′ that are not masked by the second patterned etch mask layer 79. The second anisotropic etch process has an etch chemistry that etches the materials of the in-process layer stacks (52′, 54′, 56′) and the in-process sidewall liners 58′ selectively to the material of the dielectric material layer (such as the lower fourth interconnect-level dielectric material layer 641) embedding the tubular dielectric spacers 42.

In one embodiment, the second patterning process may pattern each contiguous combination of an in-process layer stacks (52′, 54′, 56′) and an in-process sidewall liners 58′ into multiple discrete material portions that are not adjoined to one another. In one embodiment, each patterned portion of an in-process layer stack (52′, 54′, 56′) comprises a respective layer stack including a heater liner 52, a phase change material portion 54, and a top electrode 56. Each patterned portion of an in-process sidewall liner 58′ constitutes a sidewall liner 58 according to an embodiment of the present disclosure. An in-process layer stacks (52′, 54′, 56′) may be patterned into a plurality of layer stacks (52, 54, 56). An in-process sidewall liner 58′ may be patterned into a plurality of sidewall liners 58. For each layer stack (52, 54, 56), the lateral distance between a sidewall of the layer stack (52, 54, 56) and a proximal sidewall of an underlying heater element 52 may be in a range from 30 nm to 200 nm, such as from 50 nm to 150 nm, although lesser or greater lateral distances may also be used.

Generally, at least one sidewall liner 58 may be formed on a sidewall of each layer stack (52, 54, 56), which is a patterned portion of the continuous layer stack (52L, 54L, 56L), by depositing and patterning a sidewall liner material. The sidewall liner material of the at least one sidewall liner 58 comprises a material having an electrical conductivity that is higher than an electrical conductivity of an amorphous phase of the phase change material. The sidewall liner material may comprise a metallic nitride material formed by incorporating carbon atoms or nitrogen atoms therein such that the metallic nitride material has a lower electrical conductivity than a stoichiometric metallic nitride material. Thus, in embodiments in which an amorphous phase portion of a phase change material and a sidewall liner 58 provide two parallel electrically conductive paths, the sidewall liner 58 provides a lower resistance path, and predominantly determines the total resistance of the two parallel electrically conductive paths during operation of the phase change memory cell of the present disclosure. This aspect is particularly useful for operation of the phase change memory cell for computation-in-memory (CIM) applications because the resistance drift effect of the phase change material is suppressed during operation of the phase change memory cell.

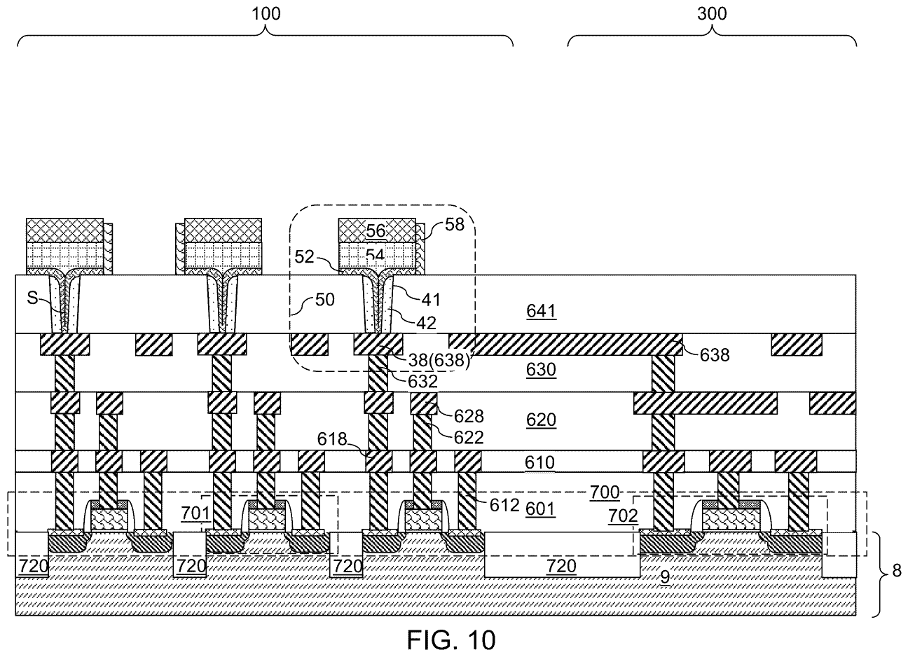

Referring to FIG. 10, the second patterned etch mask layer 79 may be removed, for example, by ashing. Each contiguous combination of a bottom electrode 38, a heater liner 52, a phase change material portion 54, a top electrode 56, and at least one sidewall liner 58 constitutes a phase change memory cell 50. The vertically-extending portion of the heater liner 52 functions as a heater element for the phase change memory cell 50, and provides various types of thermal pulses that is necessary to program the phase change material portion 54 into a target resistive state upon application of a suitable programming pulse, i.e., an electrical current pulse, between the bottom electrode 38 and the top electrode 56.

In one embodiment, each phase change memory cell 50 comprises: a tubular dielectric spacer 42 located within a via opening 41 in a dielectric material layer (such as the lower fourth interconnect-level dielectric material layer 641); a heater liner 52 comprising a vertically-extending portion laterally surrounded by the tubular dielectric spacer 42 and a horizontally-extending portion overlying a top surface segment of the dielectric material layer (such as the lower fourth interconnect-level dielectric material layer 641); a phase change material portion 54 comprising a phase change material contacting a top surface of the heater liner layer 52L; and a top electrode 56 contacting a top surface of the phase change material portion 54.

In one embodiment, the heater liner 52 comprises a planar horizontal surface segment PHSS that overlies the dielectric material layer (such as the lower fourth interconnect-level dielectric material layer 641) and further comprises an annular convex surface segment ACSS that is adjoined to a periphery of an opening in the planar horizontal surface segment PHSS and overlies the via opening 41; and the phase change material portion 54 contacts the annular convex surface segment ACSS.

In one embodiment, the vertically-extending portion of the heater liner 52 comprises a vertically-extending seam S; and a top surface of the heater liner 52 comprises an annular convex surface segment ACSS having a bottom tip point that adjoins a top end of the vertically-extending seam S. In one embodiment, the phase change material portion 54 comprises a vertically-extending portion located within a center region of the via opening 41; and the vertically-extending portion of the heater liner 52 comprises a cylindrical inner sidewall contacting the vertically-extending portion of the phase change material portion 54.

In one embodiment, the phase change memory cell 50 comprises at least one sidewall liner 58 located on at least one sidewall of the phase change material portion 54, contacting a sidewall of the horizontally-extending portion of the heater liner 52, and comprising a material having an electrical conductivity that is higher than an electrical conductivity of an amorphous phase of the phase change material.

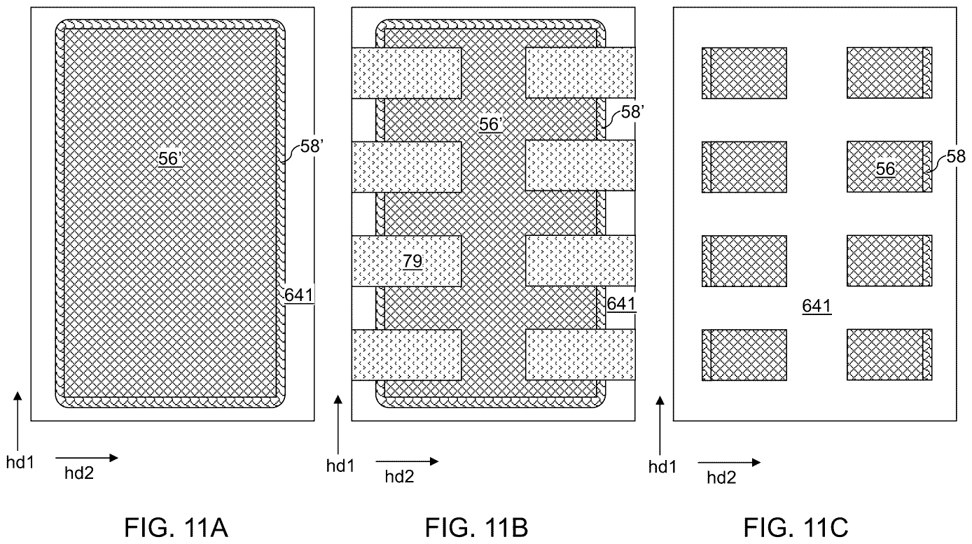

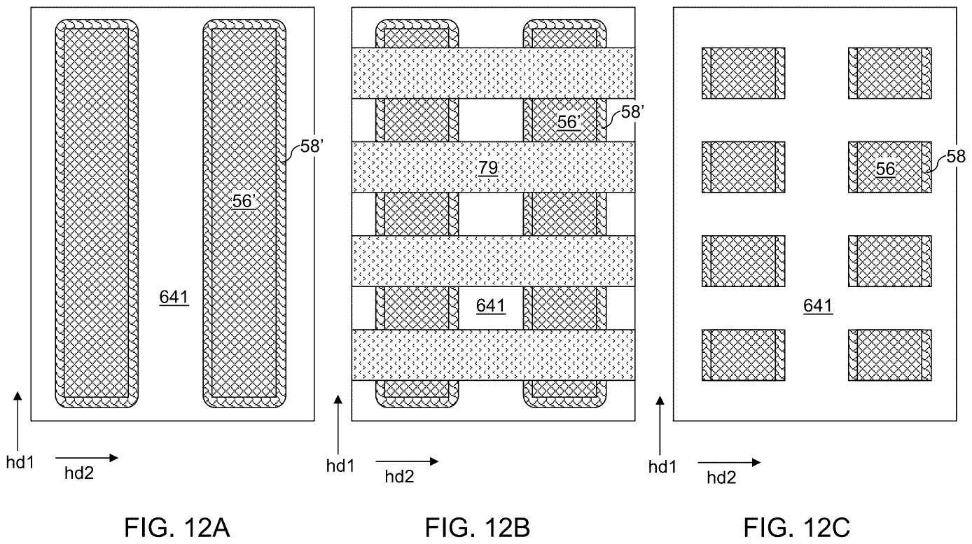

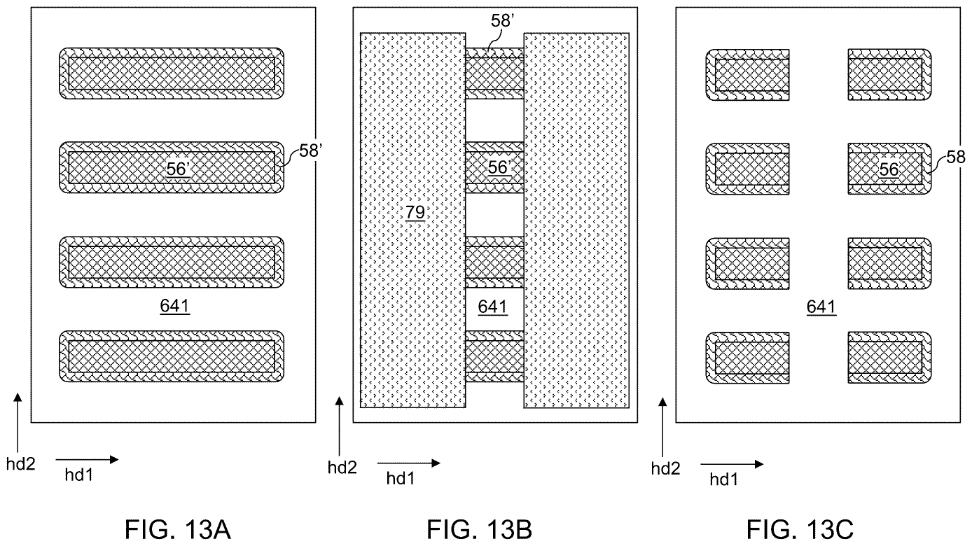

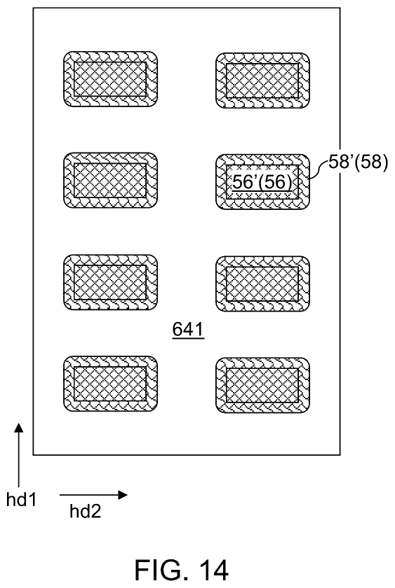

Generally, the first patterning process described with reference to FIG. 8 and the second patterning process described with reference to FIG. 11 may use various combinations of patterns to provide an array of phase change memory cells 50 having different configurations. FIGS. 11A-11C illustrate sequential top-down views of a region of a first configuration of the embodiment structure during the processing steps of FIGS. 8-10. FIGS. 12A-12C illustrate sequential top-down views of a region of a second configuration of the embodiment structure during the processing steps of FIGS. 8-10. FIGS. 13A-13C illustrate sequential top-down views of a region of a third configuration of the embodiment structure during the processing steps of FIGS. 8-10. FIG. 14 illustrates a top-down view of a region of a fourth configuration of the embodiment structure after the processing steps of FIG. 8. The various configurations illustrated in FIGS. 11A-14 are mere illustrations that describe specific configurations, and do not limit the scope of the present disclosure.

Referring to FIG. 11A, a region of a first configuration of the embodiment structure including an in-process layer stack (52′, 54′, 56′) and an in-process sidewall liner 58′ is illustrated at a processing step of FIG. 8. The in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 11B, the region of the first configuration of the embodiment structure is illustrated after formation of the second patterned etch mask layer 79 and prior to performing the second anisotropic etch process. The second patterned etch mask layer 79 may comprise a two-dimensional array, such as a 2×N array, of patterned discrete etch mask material portions (such as patterned photoresist material portions) that cover 2N segments of the first sidewalls of the in-process layer stack (52′, 54′, 56′). In the illustrated example, the integer N is 4. Generally, the integer N may be any positive integer. As discussed above, the in-process layer stack (52′, 54′, 56′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 11C, the second anisotropic etch process may be performed as described with reference to FIG. 9. The second anisotropic etch process removes unmasked portions of the in-process layer stack (52′, 54′, 56′) that are not covered by the second patterned etch mask layer 79. Each patterned portion of the in-process layer stack (52′, 54′, 56′) comprises a layer stack (52, 54, 56) including a respective heater liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the first configuration illustrated in FIG. 11C, the at least one row of patterned portions may comprise two rows of patterned portions of the in-process layer stack (52′, 54′, 56′), i.e., two rows of layer stacks (52, 54, 56) that constitute a 2×N array of layer stacks (52, 54, 56). Generally, a P×Q array of in-process layer stacks (52′, 54′, 56′) may be used, and a 2P×QN array of phase change memory cells 50 may be formed by using the first configuration illustrated in FIGS. 11A-11C.

Generally speaking, the at least one sidewall liner 58 may be formed on each layer stack (52, 54, 56) within each phase change memory cell 50. In the first configuration, the at least one sidewall liner 58 within each phase change memory cell 50 may consist of a single sidewall liner 58 that is formed directly on a sidewall of the layer stack (52, 54, 56) of the phase change memory cell 50, which is a patterned portion of the continuous layer stack (52L, 54L, 56L).

Referring to FIG. 12A, a region of a second configuration of the embodiment structure including two in-process layer stacks (52′, 54′, 56′) and two in-process sidewall liners 58′ is illustrated at a processing step of FIG. 8. Each in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 12B, the region of the second configuration of the embodiment structure is illustrated after formation of the second patterned etch mask layer 79 and prior to performing the second anisotropic etch process. The second patterned etch mask layer 79 may comprise a 1×N array of patterned discrete etch mask material portions (such as patterned photoresist material portions) that cover 2N segments of the first sidewalls of each in-process layer stack (52′, 54′, 56′). Each patterned discrete etch mask material portion may comprise a photoresist material strip that laterally extends along the second horizontal direction hd2 and having a uniform width along the first horizontal direction hd1. In the illustrated example, the integer N is 4. Generally, the integer N may be any positive integer. As discussed above, each in-process layer stack (52′, 54′, 56′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 12C, the second anisotropic etch process may be performed as described with reference to FIG. 9. The second anisotropic etch process removes unmasked portions of the in-process layer stack (52′, 54′, 56′) that are not covered by the second patterned etch mask layer 79. Each patterned portion of the in-process layer stack (52′, 54′, 56′) comprises a layer stack (52, 54, 56) including a respective heater liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the second configuration illustrated in FIG. 12C, the at least one row of patterned portions may comprise a row of patterned portions of the in-process layer stack (52′, 54′, 56′), i.e., a row of layer stacks (52, 54, 56) that constitutes a 1×N array of layer stacks (52, 54, 56). Generally, a P×Q array of in-process layer stacks (52′, 54′, 56′) may be used, and a P×QN array of phase change memory cells 50 may be formed by using the second configuration illustrated in FIGS. 12A-12C.

Generally speaking, the at least one sidewall liner 58 may be formed on each layer stack (52, 54, 56) within each phase change memory cell 50. In the second configuration, the at least one sidewall liner 58 within each phase change memory cell 50 may comprise two sidewall liners 58 that are formed directly on a pair of sidewalls of the layer stack (52, 54, 56) of the phase change memory cell 50, which is a patterned portion of the continuous layer stack (52L, 54L, 56L). The pair of sidewalls may be parallel to each other, and the two sidewall liners 58 are laterally spaced apart from each other along a horizontal direction such as the second horizontal direction hd2.

Referring to FIG. 13A, a region of a third configuration of the embodiment structure including in-process layer stacks (52′, 54′, 56′) and in-process sidewall liners 58′ is illustrated at a processing step of FIG. 10. Each in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 13B, the region of the third configuration of the embodiment structure is illustrated after formation of the second patterned etch mask layer 79 and prior to performing the second anisotropic etch process. The second patterned etch mask layer 79 may comprise a pair of patterned discrete etch mask material portions (such as patterned photoresist material portions) that cover all second sidewalls of the in-process layer stacks (52′, 54′, 56′) and segments of each first sidewall that are adjoined to a respective second sidewall of the in-process layer stacks (52′, 54′, 56′). Each first sidewall of the in-process layer stacks (52′, 54′, 56′) comprises a central segment that is not covered by the second patterned etch mask layer 79. As discussed above, each in-process layer stack (52′, 54′, 56′) comprises first sidewalls that laterally extend along the first horizontal direction hd1 and second sidewalls that laterally extend along the second horizontal direction hd2. The two masking material portions of the second patterned etch mask layer 79 laterally extend along the second horizontal direction hd2, and may be laterally spaced apart from one another along the first horizontal direction hd1 so that central segments of each first sidewall of the in-process layer stacks (52′, 54′, 56′) are not covered by the second patterned etch mask layer 79.

Referring to FIG. 13C, the second anisotropic etch process may be performed as described with reference to FIG. 9. The second anisotropic etch process removes unmasked portions of the in-process layer stacks (52′, 54′, 56′) that are not covered by the second patterned etch mask layer 79. Each patterned portion of the in-process layer stacks (52′, 54′, 56′) comprises a layer stack (52, 54, 56) including a respective heater liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the third configuration illustrated in FIG. 13C, the at least one row of patterned portions may comprise a row including two patterned portions of the in-process layer stack (52′, 54′, 56′), i.e., a row of layer stacks (52, 54, 56) that constitutes a 1×2 array of layer stacks (52, 54, 56). Generally, a P×Q array of in-process layer stacks (52′, 54′, 56′) may be used, and a P×2Q array of phase change memory cells 50 may be formed by using the third configuration illustrated in FIGS. 13A-13C.

Generally speaking, the at least one sidewall liner 58 may be formed on each layer stack (52, 54, 56) within each phase change memory cell 50. In the third configuration, the at least one sidewall liner 58 within each phase change memory cell 50 may consist of a single sidewall liner 58 that is formed directly on three sidewalls of the layer stack (52, 54, 56) of the phase change memory cell 50, which is a patterned portion of the continuous layer stack (52L, 54L, 56L).

Referring to FIG. 14, a fourth configuration of the embodiment structure is illustrated after the processing steps of FIG. 8. In the fourth configuration, the masking pattern of the first patterned etch mask layer 77 used at the processing steps of FIG. 8 is modified such that the pattern of the first patterned etch mask layer 77 is the same as the target pattern for an array of layer stacks (52, 54, 56) for an array of phase change memory cells 50. In this embodiment, the first anisotropic etch process described with reference to FIG. 6 patterns the continuous layer stack (52L, 54L, 56L) directly into the array of layer stacks (52, 54, 56). Further, upon performing the processing steps described with reference to FIGS. 7 and 8, the sidewall liner layer 58L may be patterned directly into the sidewall liners 58. Therefore, the processing steps described with reference to FIGS. 9 and 10 may be omitted if the fourth configuration of the embodiment structure is used.

Generally speaking, the at least one sidewall liner 58 may be formed on each layer stack (52, 54, 56) within each phase change memory cell 50. In the fourth configuration, the at least one sidewall liner 58 within each phase change memory cell 50 may have an annular configuration. In other words, the at least one sidewall liner 58 within each phase change memory cell 50 may consist of a single sidewall liner 58 that is topologically homeomorphic to a torus, i.e., may be continuous deformed without formation of a new hole and without elimination of any pre-existing hole into a torus. The single sidewall liner 58 may be formed directly on each sidewall of a respective layer stack (52, 54, 56), which is a patterned portion of the continuous layer stack (52L, 54L, 56L).

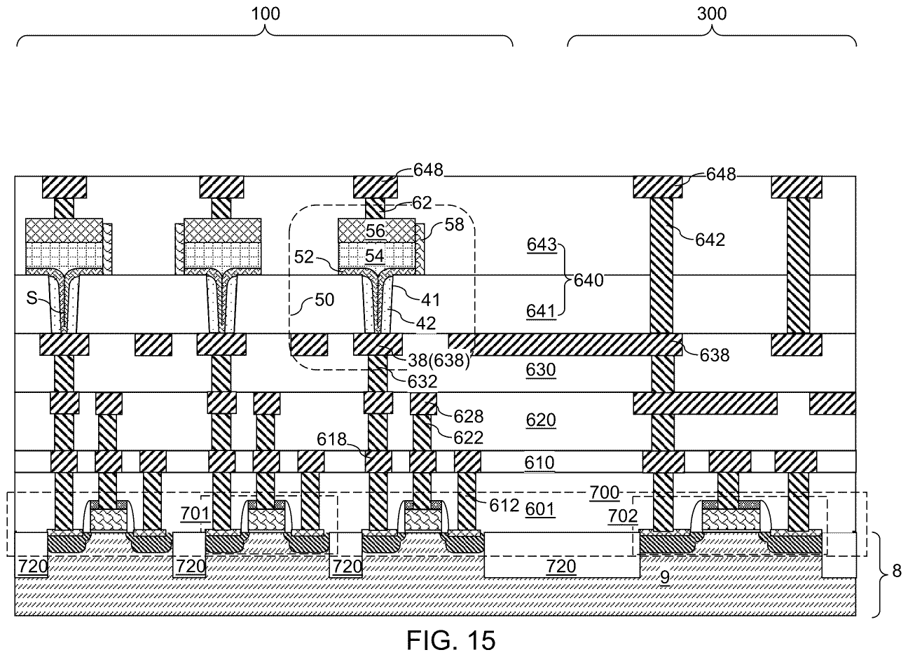

Referring to FIG. 15, an encapsulation dielectric layer 643 and additional metal interconnect structures (62, 642, 648) may be formed over the phase change memory cells 50. The encapsulation dielectric layer 643 comprises at least one interlayer dielectric material such as silicon oxide, silicon nitride, and/or silicon carbide nitride. The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. The additional metal interconnect structures (62, 642, 648) may comprise top-contact via structures 62 contacting a top surface of a respective one of the top electrodes 56, third metal via structures 642 that are formed through a lower portion of the fourth interconnect-level dielectric material layer 640, and fourth metal line structures 648 that are formed on the top-contact via structures 62 and the third metal via structures 642 in an upper portion of the fourth interconnect-level dielectric material layer 640. Top surfaces of the fourth metal line structures 648 may be coplanar with the horizontal top surface of the encapsulation dielectric layer 643. Additional dielectric material layers (not shown) and additional metal interconnect structures may be formed as needed to provide electrical connections between the top electrodes 56 of the phase change memory cells 50 and the various semiconductor devices 700 that underlie the dielectric material layers (601, 610, 620, 630, 640).

Generally, programming transistors 701 may be provided on a substrate 8. Metal interconnect structures (612, 618, 622, 628, 632, 638) embedded within interconnect-level dielectric material layers (601, 610, 620, 630, 641) may be formed over the programming transistors 701. Bottom electrodes 38 and tubular dielectric spacers 42 may be formed within a dielectric material layer, such as a lower fourth interconnect-level dielectric material layer 641. Each heater liner 52 may be electrically connected to an electrical node, such as an output node, of a respective programming transistor 701. A continuous layer stack (52L, 54L, 56L) including a heater liner layer 52L, a phase change material layer 54L comprising a phase change material, and a top electrode material layer 56L may be deposited and patterned to form layer stacks (52, 54, 56) of a heater liner 52, a phase change material portion 54, and a top electrode 56. A sidewall liner layer 58L may be formed and patterned to form sidewall liners 58. At least one sidewall liner 58 may be formed on at least one sidewall of each layer stack (52, 54, 56).

Each sidewall liner 58 comprises a material having an electrical conductivity that is higher than an electrical conductivity of an amorphous phase of the phase change material of the phase change material portions 54. For each phase change memory cell 50, an encapsulation dielectric layer 643 may be deposited directly on at least one sidewall of the layer stack (52, 54, 56) (which is a patterned portion of the continuous layer stack (52L, 54L, 56L)) and directly on an outer sidewall of each of the at least one sidewall liner 58 and directly on a top surface of the layer stack (52, 54, 56). Thus, for each phase change memory cell 50, the encapsulation dielectric layer 643 is in contact with at least one sidewall of the layer stack, an outer sidewall of each of the at least one sidewall liner 58, and a top surface of the layer stack (52, 54, 56).

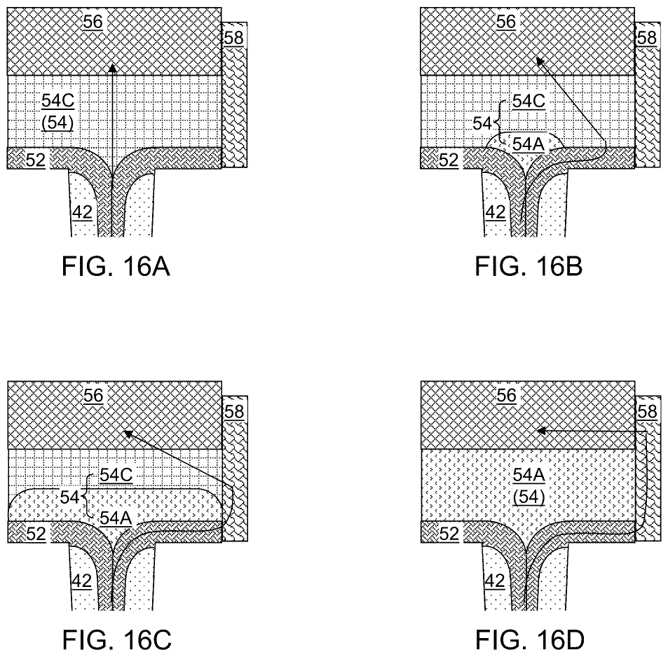

For each phase change memory cell 50 that is electrically connected to a programming transistor 701, the programming transistor 701 is configured to program the phase change memory cell 50 into at least three different resistive states by applying at least three different programming pulse patterns to the heater liner 52. FIGS. 16A-16D are various configurations of a phase change material portion 54 in various programmed resistance states according to an embodiment of the present disclosure.

Referring to FIG. 16A, a phase change memory cell 50 in a low resistance state is illustrated. In this embodiment, at least 99% of the entire volume of the phase change material portion 54 is in a polycrystalline phase. In one embodiment, the entirety of the phase change material portion 54 may be a crystalline phase change material portion 54C including a polycrystalline phase change material. The electrical conductivity of the crystalline phase change material is higher than the electrical conductivity of the materials of the heater liner 52 and the at least one sidewall liner 58. Thus, the primary electrically conductive path extends vertically between the heater liner 52 and the top electrode 56.

Referring to FIG. 16B, a phase change memory cell 50 in a first intermediate state is illustrated. In this embodiment, the phase change material portion 54 comprises a first volume having the amorphous phase and a second volume having the crystalline phase. The first volume comprises an amorphous phase change material portion 54A, and the second volume comprises a crystalline phase change material portion 54C. The first volume is not in direct contact with the at least one sidewall liner 58. The electrical conductivity of the amorphous phase change material is lower than the electrical conductivity of the materials of the heater liner 52 and the at least one sidewall liner 58. Thus, the primary electrically conductive path extends laterally within the heater liner 52 underneath the amorphous phase change material portion 54A and extends through the crystalline phase change material portion 54C between a peripheral portion of the heater liner 52 and the top electrode 56 at an angle relative to the vertical direction.

Referring to FIG. 16C, a phase change memory cell 50 in a second intermediate state providing a higher resistance than the first intermediate state is illustrated. In this embodiment, the phase change material portion 54 comprises a first volume having the amorphous phase and a second volume having the crystalline phase. The first volume comprises an amorphous phase change material portion 54A, and the second volume comprises a crystalline phase change material portion 54C. The first volume is in direct contact with the at least one sidewall liner 58, and does not contact the top electrode 56. The electrical conductivity of the amorphous phase change material is lower than the electrical conductivity of the materials of the heater liner 52 and the at least one sidewall liner 58. Thus, the primary electrically conductive path extends laterally within the heater liner 52 underneath the amorphous phase change material portion 54A, extends vertically through a lower portion of each sidewall liner 58, and extends through the crystalline phase change material portion 54C between a middle portion of each sidewall liner 58 and the top electrode 56 at an angle relative to the vertical direction.

Referring to FIG. 16D, a phase change memory cell 50 in a high resistance state is illustrated. In this embodiment, at least 99% of an entire volume of the phase change material portion 54 is in an amorphous phase.

While four resistive states of a phase change memory cell 50 are illustrated in FIGS. 16A-16D, the pulse pattern of the programming pulse from the programming transistor 701 may be pre-programmed to be selected from a plurality of programming pulse patterns that is stored in a programming circuit for the phase change memory cells 50. The total number of pre-programmed pulse patterns may be in a range from 2 to 210, such as from 3 to 28, and/or from 4 to 26. The total number of resistive states that may be programmed in each phase change memory cell 50 may be the same as the total number of pre-programmed pulse patterns. In one embodiment, each programming transistor 701 may be configured to apply at least four different programming pulse patterns to a respective heater liner 52. The programming pulses may have a respective duration and/or voltage ramp-down rate to provide a controlled rate of cooling of a molten region of a phase change material portion 54. The duration of the programming pulses may be in a range from 10 nanoseconds to 500 nanoseconds, the longer programming pulses generally corresponding to formation of large crystallized regions of the phase change material portion 54.

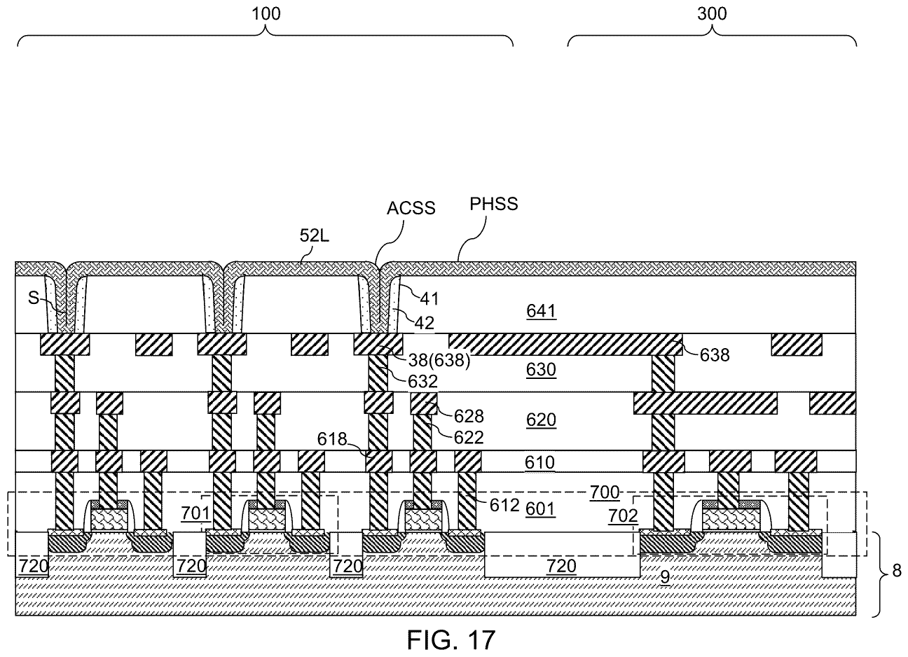

Referring to FIG. 17, a second embodiment structure according to an embodiment of the present disclosure is illustrated. The second embodiment structure may be derived from the first embodiment structure illustrated in FIG. 1 by forming the via openings 41 with a larger lateral dimension, and by performing the processing steps described with reference to FIGS. 3 and 4, and by depositing a heater liner layer 52L having a greater thickness than the heater liner layer 52L described with reference to FIG. 5.

For example, the lateral dimension (such as the diameter) of the bottom portion of each via opening 41, as formed at a processing step corresponding to the processing step of FIG. 2, may be in a range from 80 nm to 400 nm, although lesser or greater lateral dimensions may also be used. The thickness of the dielectric spacer material layer 42L, as deposited at a processing step corresponding to the processing step of FIG. 3, is selected such that the difference between the width of the bottom portion of each via opening 41 and twice the thickness of the dielectric spacer material layer 42L is greater than a target range for the width of the bottom portion of each vertically-extending portion of a heater liner layer to be subsequently formed. In an illustrative example, if the width of the bottom portion of each via opening 41 is in a range from 80 nm to 400 nm and if the target range for the width of the bottom portion of each vertically-extending portion of the heater liner layer 52L is in a range from 20 nm to 100 nm, the thickness of the dielectric spacer material layer 42L may be in a range from 15 nm to 150 nm, such as from 30 nm to 80 nm, although lesser or greater thicknesses may also be used. As such, the lateral distance between the inner cylindrical sidewall and an outer cylindrical sidewall of each tubular dielectric spacer 42 may be approximately in a range from 15 nm to 150 nm, such as from 30 nm to 80 nm, although lesser or greater lateral distances may also be used.

The heater liner layer 52L may be deposited with a sufficient thickness to provide filling of a predominant fraction, and/or the entirety, of the volume of each void within the via openings 41 is filled with the deposited material of the heater liner layer 52L. The thickness of the horizontally-extending portion of the heater liner layer 52L that is formed over the top surface of the dielectric material layer (such as the lower fourth interconnect-level dielectric material layer 641) may be in a range from 25 nm to 120 nm, such as from 50 nm to 80 nm, although lesser or greater thicknesses may also be used.

As in the first embodiment structure, a vertically-extending seam S may be formed within each vertically-extending portion of the heater liner layer 52L that is deposited within a fraction of the volume of a respective via opening 41. Another fraction of the volume of the respective via opening 41 may be occupied by a tubular dielectric spacer 42. As in the first embodiment structure, the heater liner layer 52L is formed with a planar horizontal surface segment PHSS that overlies the dielectric material layer (such as the lower fourth interconnect-level dielectric material layer 641), and annular convex surface segments ACSS, each being adjoined to a periphery of a respective opening in the planar horizontal surface segment PHSS and comprising a respective bottom tip point that adjoins a top end of the vertically-extending seam S.

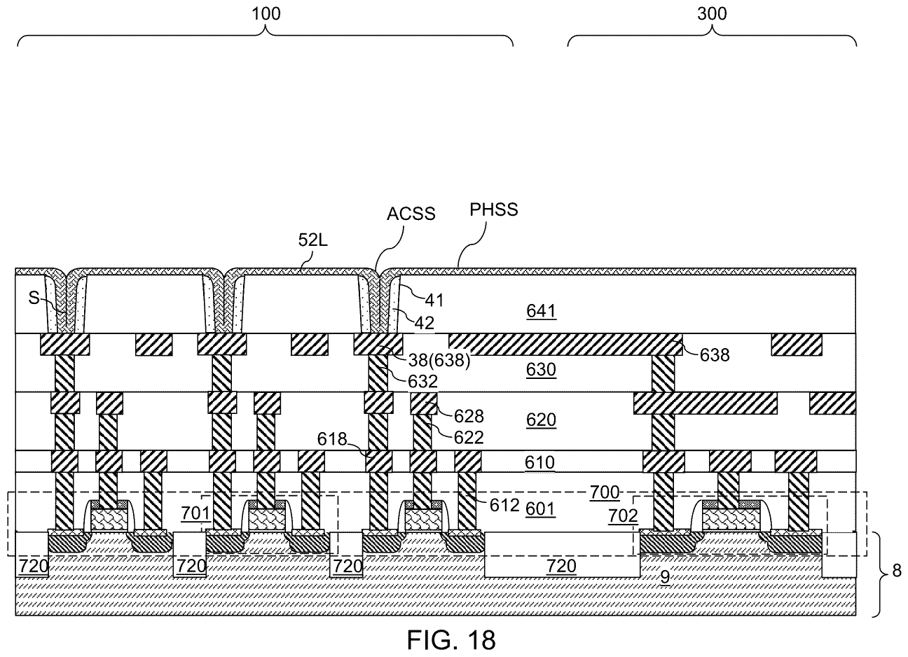

Referring to FIG. 18, the heater liner layer 52L may be vertically recessed by performing an etch-back process, which is a recess etch process that etches the material of the heater liner layer 52L. The etch-back process vertically recesses the horizontally-extending portion of the heater liner layer 52L. The etch-back process vertically recesses the annular convex surface segments ACSS of the heater liner layer 52L simultaneously while vertically recessing the horizontally-extending portion of the heater liner layer 52L. In other words, the etch-back process etches the annular convex surface segments ACSS and the planar horizontal surface segment PHSS of the heater liner layer 52L are simultaneously.

The etch-back process may comprise a wet etch process, or a reactive ion etch process. The duration of the etch-back process may be selected such that the thinned horizontally-extending portion of the heater liner layer 52L has a thickness within a target thickness range, which may be in a range from 1 nm to 50 nm, such as from 3 nm to 20 nm, although lesser or greater thicknesses may also be used. Generally, the thickness of the horizontally-extending portion of the heater liner layer 52L formed through the processing steps described with reference to FIGS. 17 and 18 may be less than the thickness of the horizontally-extending portion of the heater liner layer 52L within the first embodiment structure, and a higher electrical resistance may be provided by the horizontally-extending portion of the heater liner layer 52L of the second embodiment structure relative to the horizontally-extending portion of the heater liner layer 52L of the first embodiment structure.

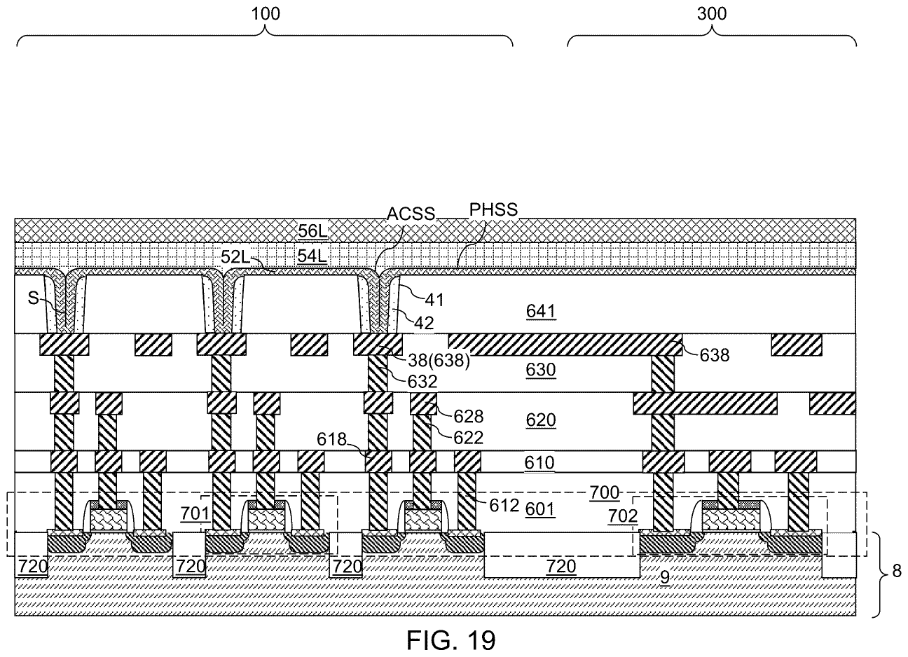

Referring to FIG. 19, a subset of the processing steps described with reference to FIG. 5 may be performed to deposit a phase change material layer 54L and a top electrode material layer 56L over the horizontally-extending portion of the heater liner layer 52L.

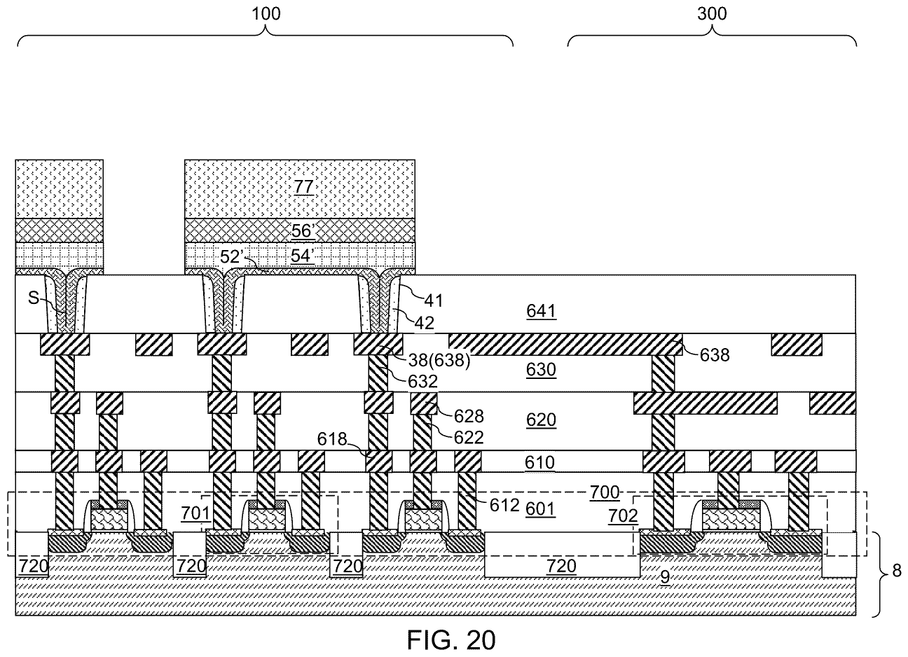

Referring to FIG. 20, the processing steps described with reference to FIG. 6 may be performed to pattern the continuous layer stack (52L, 54L, 56L) into a two-dimensional array of in-process layer stacks (52′, 54′, 56′).

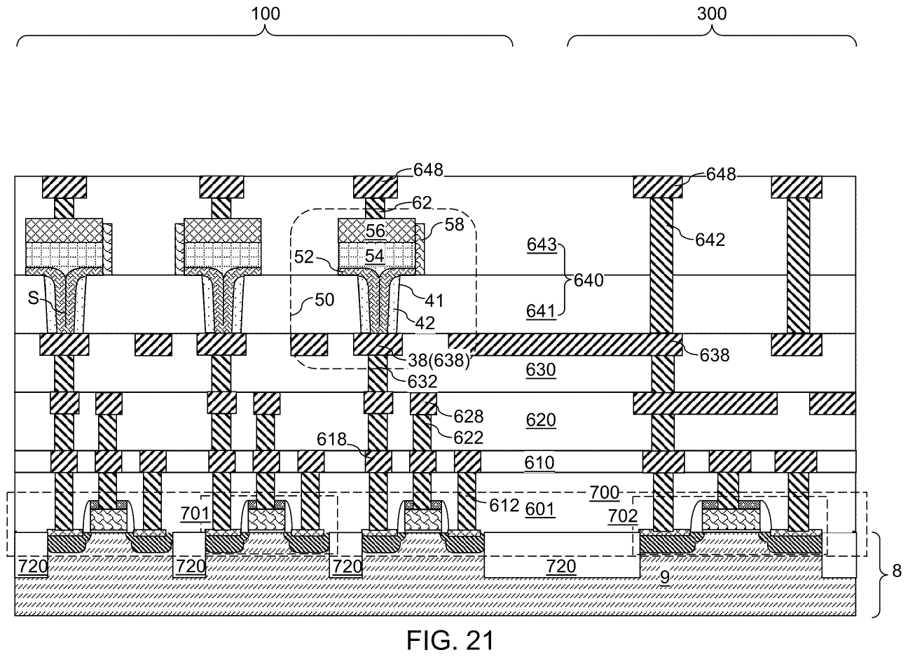

Referring to FIG. 21, the processing steps described with reference to FIGS. 7-15 may be performed to form a two-dimensional array of phase change memory devices 50. Each phase change memory cell 50 of the second embodiment structure may have a greater bottom width for the vertically-extending portion of a heater liner 52 and/or a lesser thickness for the horizontally-extending portion of the heater liner 52, which may be advantageously used to provide enhanced resistance distribution characteristics for the various programmed states of the phase change memory cell 50.

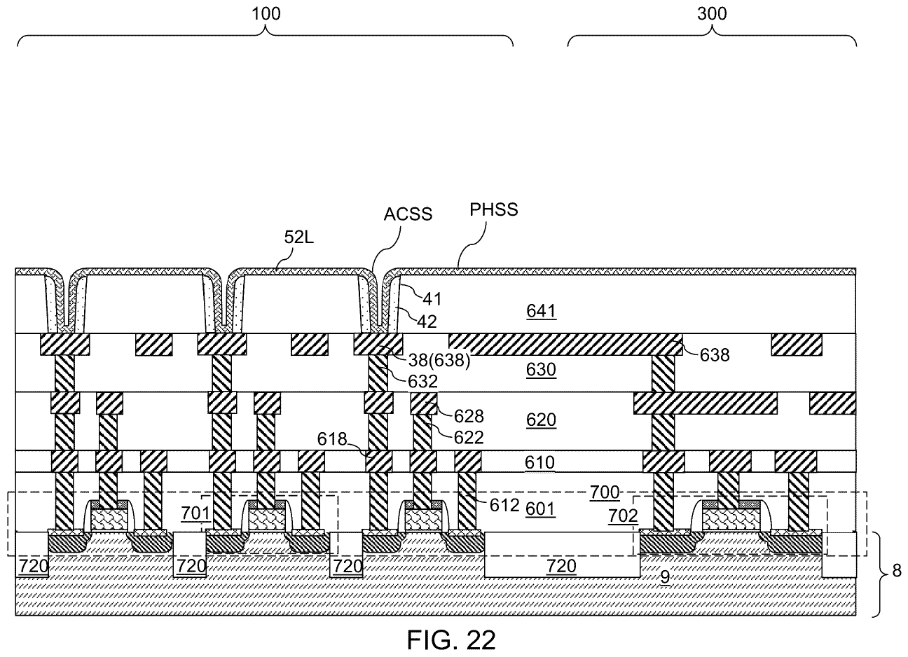

Referring to FIG. 22, a third embodiment structure according to an embodiment of the present disclosure is illustrated after formation of a heater liner layer 52L. The third embodiment structure may be derived from the first embodiment structure illustrated in FIG. 1 by forming the via openings 41 with a larger lateral dimension, and by performing the processing steps described with reference to FIGS. 3 and 4, and by depositing a heater liner layer 52L having a same thickness range as the heater liner layer 52L described with reference to FIG. 5. The heater liner layer 52L may be deposited by a conformal deposition process.

As described above, a void may be present within each volume that is laterally surrounded by a tubular dielectric spacer 42. In the third embodiment structure, the maximum width of each void within the volumes of the via openings 41 is greater than one half of the thickness of the heater liner layer 52L. Thus, the voids in the volumes of the via openings 41 are not completely filled by the heater liner layer 52L. In other words, an unfilled portion of a void may be present within each volume of the via openings 41 after formation of the heater liner layer 52L. in one embodiment, an inner cylindrical sidewall of a tubular portion the heater liner layer 52L and a top surface segment of a horizontally-extending portion of the heater liner layer 52L contacting a respective underlying bottom electrode 38 may be physically exposed to each unfilled void that is present within the volume of a respective via opening 41 through the dielectric material layer (such as the lower fourth interconnect-level dielectric material layer 641).

As in the first embodiment structure, the heater liner layer 52L is formed with a planar horizontal surface segment PHSS that overlies the dielectric material layer (such as the lower fourth interconnect-level dielectric material layer 641), and annular convex surface segments ACSS each adjoined to a periphery of a respective opening in the planar horizontal surface segment PHSS and comprising a respective bottom tip point that adjoins a top end of the vertically-extending seam S.

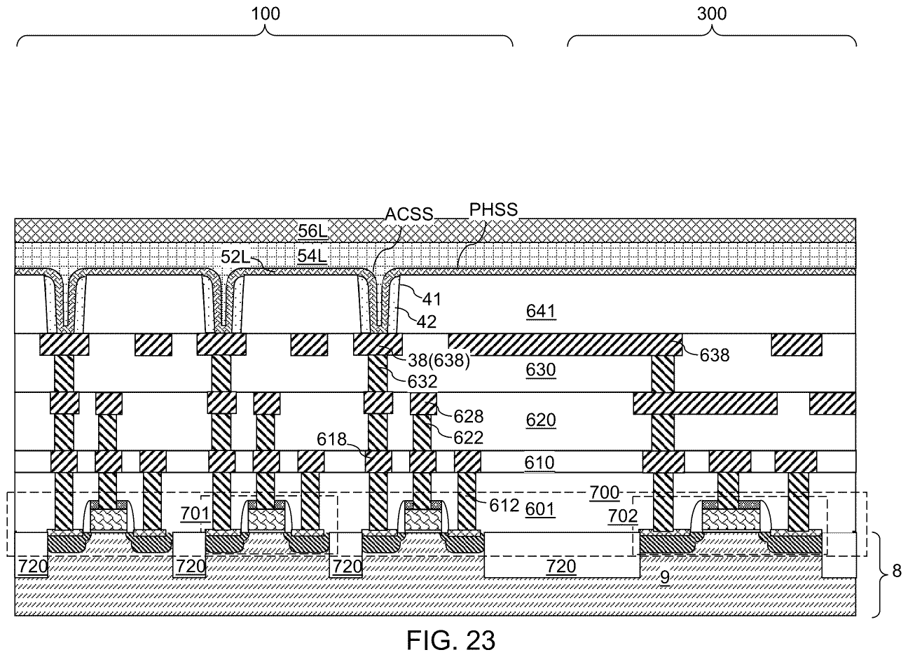

Referring to FIG. 23, a subset of the processing steps described with reference to FIG. 5 may be performed to deposit a phase change material layer 54L and the top electrode material layer 56L. In the third embodiment structure, the phase change material layer 54L comprises vertically-extending portions each having a cylindrical sidewall that contacts a respective inner cylindrical sidewall of the tubular dielectric spacer 42 within the volume of a respective via opening 41 that vertically extends through the dielectric material layer (such as the lower fourth interconnect-level dielectric material layer 641). Each vertically-extending portion of the phase change material layer 54L may be deposited within the unfilled portion of a respective void that is laterally surrounded by a respective tubular portion of the heater liner layer 52L. The top electrode material layer 56L is subsequently deposited over the phase change material layer 54L.

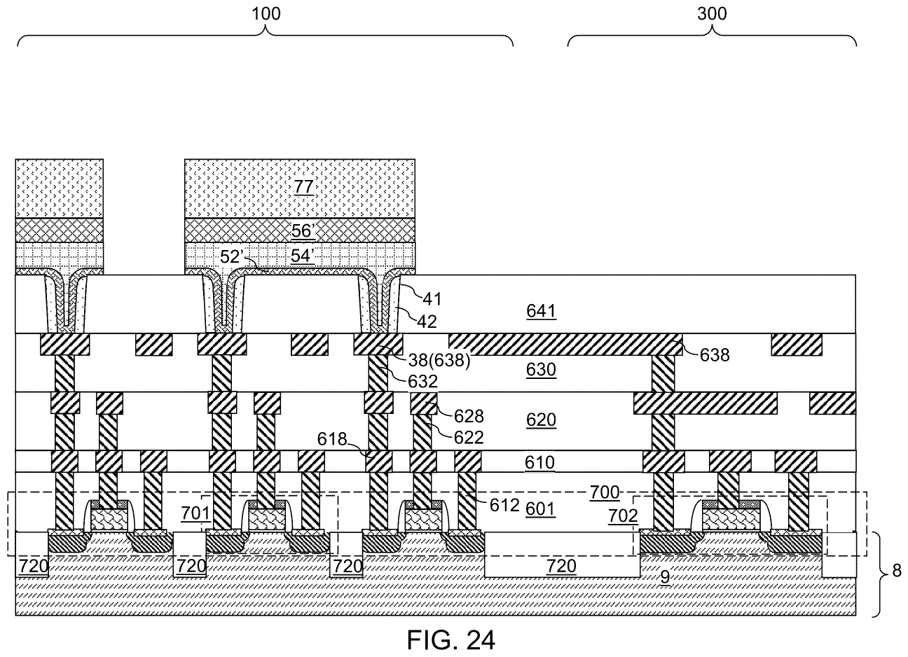

Referring to FIG. 24, the processing steps described with reference to FIG. 6 may be performed to pattern the continuous layer stack (52L, 54L, 56L) into a two-dimensional array of in-process layer stacks (52′, 54′, 56′).

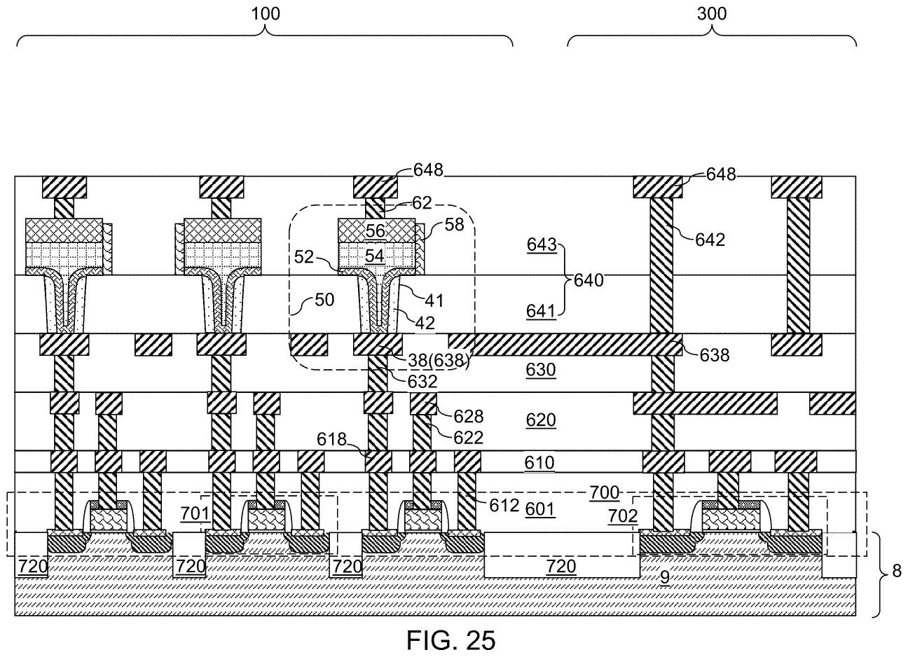

Referring to FIG. 25, the processing steps described with reference to FIGS. 7-15 may be performed to form a two-dimensional array of phase change memory devices 50. Each phase change memory cell 50 of the third embodiment structure may have tubular vertically-extending portions of a heater liner 52. In one embodiment, the lateral thickness of the tubular vertically-extending portions of the heater liner 52 (as measured between a cylindrical inner sidewall and a cylindrical outer sidewall) and the vertical thickness of the horizontally-extending portion of the heater liner 52 that overlies the dielectric material layer through which the via openings 41 vertically extend may be the same.

Referring collectively to FIGS. 1-25 and according to various embodiments of the present disclosure, a device structure is provided, which comprises: a tubular dielectric spacer 42 located within a via opening 41 in a dielectric material layer (such as the lower fourth interconnect-level dielectric material layer 641); a heater liner 52 comprising a vertically-extending portion laterally surrounded by the tubular dielectric spacer 42 and a horizontally-extending portion overlying a top surface segment of the dielectric material layer (such as the lower fourth interconnect-level dielectric material layer 641); a phase change material portion 54 comprising a phase change material contacting a top surface of the heater liner layer 52L; and a top electrode 56 contacting a top surface of the phase change material portion 54.

In one embodiment, the heater liner 52 comprises a planar horizontal surface segment PHSS that overlies the dielectric material layer (such as the lower fourth interconnect-level dielectric material layer 641) and further comprises an annular convex surface segment ACSS that is adjoined to a periphery of an opening in the planar horizontal surface segment PHSS and overlies the via opening 41; and the phase change material portion 54 contacts the annular convex surface segment ACSS.

In one embodiment, the vertically-extending portion of the heater liner 52 comprises a vertically-extending seam S; and a top surface of the heater liner 52 comprises an annular convex surface segment ACSS having a bottom tip point that adjoins a top end of the vertically-extending seam S.

In one embodiment, the phase change material portion 54 comprises a vertically-extending portion located within a center region of the via opening 41; and the vertically-extending portion of the heater liner 52 comprises a cylindrical inner sidewall contacting the vertically-extending portion of the phase change material portion 54.

In one embodiment, the device structure comprises at least one sidewall liner 58 located on at least one sidewall of the phase change material portion 54, contacting a sidewall of the horizontally-extending portion of the heater liner 52, and comprising a material having an electrical conductivity that is higher than an electrical conductivity of an amorphous phase of the phase change material.

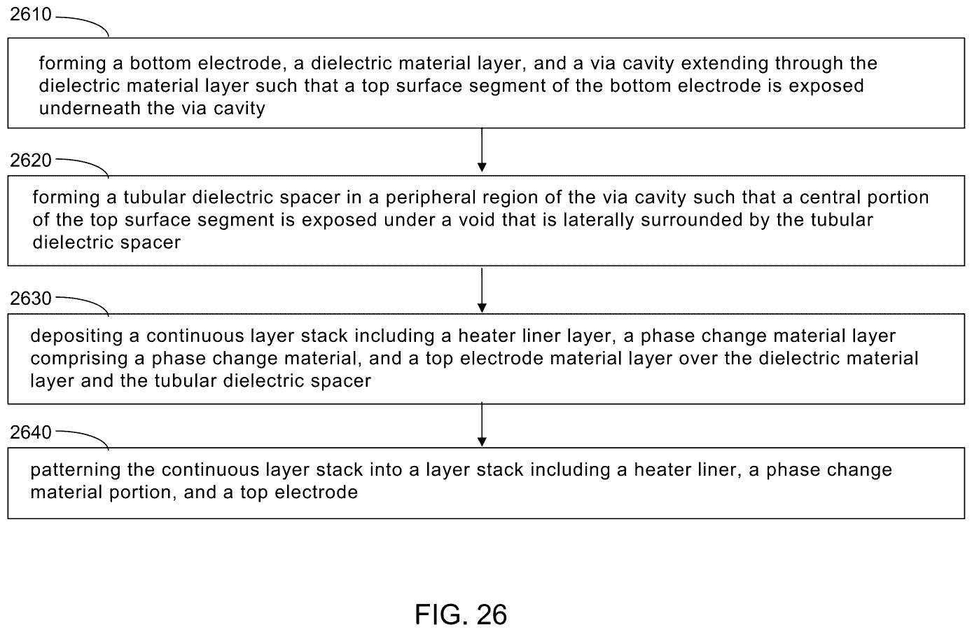

FIG. 26 is a first flowchart that illustrates general processing steps for manufacturing a device structure according to embodiments of the present disclosure.

Referring to step 2610 and FIGS. 1-2, 17, and 22, a bottom electrode 38, a dielectric material layer (such as the lower fourth interconnect-level dielectric material layer 641), and a via opening 41 extending through the dielectric material layer (such as the lower fourth interconnect-level dielectric material layer 641) may be formed such that a top surface segment of the bottom electrode 38 is exposed underneath the via opening 41.

Referring to step 2620 and FIGS. 3, 4, 17, and 22, a tubular dielectric spacer 42 may be formed in a peripheral region of the via opening 41 such that a central portion of the top surface segment is exposed under a void that is laterally surrounded by the tubular dielectric spacer 42.

Referring to step 2630 and FIGS. 5, 17 and 16, and 22 and 23, a continuous layer stack (52L, 54L, 56L) including a heater liner layer 52L, a phase change material layer 54L comprising a phase change material, and a top electrode material layer 56L may be formed over the dielectric material layer (such as the lower fourth interconnect-level dielectric material layer 641) and the tubular dielectric spacer 42.

Referring to step 2640 and FIGS. 6-16D, 19-21, and 24 and 25, the continuous layer stack (52L, 54L, 56L) may be patterned into a layer stack (52, 54, 56) including a heater liner 52, a phase change material portion 54, and a top electrode 56.

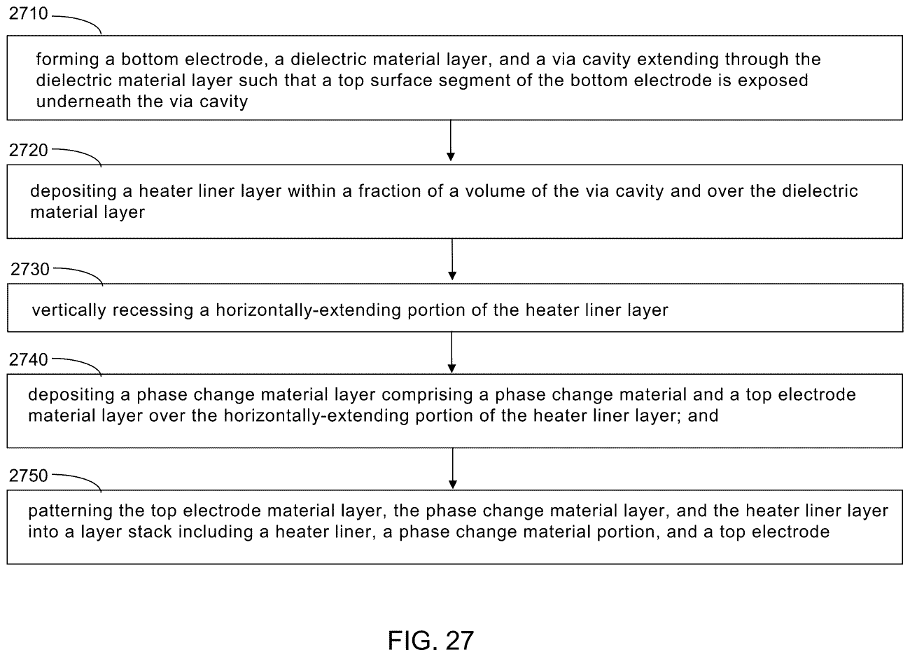

FIG. 27 is a second flowchart that illustrates general processing steps for manufacturing a device structure according to embodiments of the present disclosure.

Referring to step 2710 and FIGS. 1, 2, and 17, a bottom electrode 38, a dielectric material layer (such as the lower fourth interconnect-level dielectric material layer 641), and a via opening 41 extending through the dielectric material layer (such as the lower fourth interconnect-level dielectric material layer 641) may be formed such that a top surface segment of the bottom electrode 38 is exposed underneath the via opening 41.

Referring to step 2720 and FIGS. 3-5 and 17, a heater liner layer 52L may be deposited within a fraction of a volume of the via opening 41 and over the dielectric material layer (such as the lower fourth interconnect-level dielectric material layer 641).

Referring to step 2730 and FIG. 18, a horizontally-extending portion of the heater liner layer 52L may be vertically recessed.

Referring to step 2740 and FIG. 19, a phase change material layer 54L comprising a phase change material and a top electrode material layer 56L may be deposited over the horizontally-extending portion of the heater liner layer 52L.

Referring to step 2750 and FIGS. 6-16D, 20, and 21, the top electrode material layer 56L, the phase change material layer 54L, and the heater liner layer 52L may be patterned into a layer stack (52, 54, 56) including a heater liner 52, a phase change material portion 54, and a top electrode 56.

Within each phase change memory cell, the heater liner 52 and the sidewall liner 58 are used to set the resistance levels of high resistance states of the phase change memory cell. The combination of the heater liner 52 and the sidewall liner 58 suppresses the effect of resistance drift of the phase change material portion 54, reduces the power consumption of the phase change memory cell, reduces the error rate during operation of the phase change memory cell, and provides reduction of the cell size for the phase change memory cell. Generally, the thickness of the heater liner 52 and the thickness of the sidewall liner 58 may be optimized to provide a wide variation in the resistance of various resistive states of the phase change memory cell, and to facilitate efficient multi-level cell (MLC) operation, i.e., a cell operation in which the cell is programmed to three or more resistive states. Thus, a large programming window may be provided for use of phase change memory cells 50 for an MLC operation.

Embodiments of the present disclosure provide advancements in the processing technology for manufacture of phase change memory devices by eliminating the need for a chemical mechanical polishing (CMP) process during formation of heater elements, which comprise vertically-extending portions of the heater liners 52. In one embodiment, each heater liner 52 is formed within a via opening 41, and is laterally surrounded by a tubular dielectric spacer 42. A horizontally-extending portion of the heater liner 52 overlies a dielectric material layer through which the via openings 41 vertically extend. A phase change material portion 54 is disposed over the heater liner 52, and a top electrode 56 contacts the top surface of the phase change material portion 54. The sequence of processing steps used to form the phase change memory cells 50 reduces manufacturing complexity while improving thermal efficiency and cost-effectiveness. The phase change memory cells 50 of the present disclosure minimize thermal loss through the use of a low thermal conductivity material for the tubular dielectric spacers 42, which laterally surround the vertically-extending portions of the heater liners 52 that function as heater elements. Enhanced thermal isolation for the heater elements may enhance device performance for computation-in-memory (CIM) applications.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a bottom electrode, a dielectric material layer, and a via opening extending through the dielectric material layer such that a top surface segment of the bottom electrode is exposed underneath the via opening;
forming a tubular dielectric spacer in a peripheral region of the via opening such that a central portion of the top surface segment is exposed under a void that is laterally surrounded by the tubular dielectric spacer;
depositing a continuous layer stack including a heater liner layer, a phase change material layer comprising a phase change material, and a top electrode material layer over the dielectric material layer and the tubular dielectric spacer; and
patterning the continuous layer stack into a layer stack including a heater liner, a phase change material portion, and a top electrode.

2. The method of claim 1, wherein the heater liner layer comprises a vertically-extending portion that is deposited in a void within the tubular dielectric spacer and a horizontally-extending portion that is deposited over a top surface of the dielectric material layer.

3. The method of claim 2, wherein a vertically-extending seam is formed at a center of the vertically-extending portion of the heater liner layer.

4. The method of claim 2, wherein the phase change material layer comprises a vertically-extending portion having a cylindrical sidewall that contacts an inner cylindrical sidewall of the tubular dielectric spacer.

5. The method of claim 1, further comprising:
depositing a dielectric spacer material layer in the peripheral region of the via opening and over the dielectric material layer; and
anisotropically etching the dielectric spacer material layer, wherein a remaining vertically-extending portion of the dielectric spacer material layer that fills the peripheral region of the via opening constitutes the tubular dielectric spacer.

6. The method of claim 1, wherein:
the heater liner layer is deposited on the central portion of the top surface segment of the bottom electrode; and
the phase change material layer is deposited on a planar horizontal surface segment of the heater liner layer that overlies a horizontal plane including a top surface of the dielectric material layer.

7. The method of claim 1, wherein:
upon deposition of the heater liner layer, the heater liner layer comprises a planar horizontal surface segment that overlies the dielectric material layer and further comprises an annular convex surface segment that is adjoined to a periphery of an opening in the planar horizontal surface segment and overlies the via opening; and
the phase change material layer is deposited directly on the annular convex surface segment.

8. The method of claim 7, wherein:
the heater liner layer is deposited by a conformal deposition process;
a maximum width of the void is less than one half of a thickness of the heater liner layer; and
a vertically-extending seam is formed at a center of the void that is filled with a vertically-extending portion of the heater liner layer.

9. The method of claim 7, wherein:
the heater liner layer is deposited by a conformal deposition process;
a maximum width of the void is greater than one half of a thickness of the heater liner layer;
an unfilled portion of the void is present within a volume of the via opening after formation of the heater liner layer; and
a vertically-extending portion of the phase change material layer is deposited within the unfilled portion of the void.

10. The method of claim 1, further comprising forming at least one sidewall liner by depositing and patterning a sidewall liner material, wherein the at least one sidewall liner is formed on at least one sidewall of the layer stack, wherein the at least one sidewall liner comprises a material having an electrical conductivity that is higher than an electrical conductivity of an amorphous phase of the phase change material.

11. A method of forming a device structure, comprising:
forming a bottom electrode, a dielectric material layer, and a via opening extending through the dielectric material layer such that a top surface segment of the bottom electrode is exposed underneath the via opening;
depositing a heater liner layer within a fraction of a volume of the via opening and over the dielectric material layer;
vertically recessing a horizontally-extending portion of the heater liner layer;
depositing a phase change material layer comprising a phase change material and a top electrode material layer over the horizontally-extending portion of the heater liner layer; and
patterning the top electrode material layer, the phase change material layer, and the heater liner layer into a layer stack including a heater liner, a phase change material portion, and a top electrode.

12. The method of claim 11, further comprising forming a tubular dielectric spacer in a peripheral region of the via opening such that a central portion of the top surface segment is exposed under a void that is laterally surrounded by the tubular dielectric spacer, wherein the fraction of the volume of the via opening comprises a volume of a void within the tubular dielectric spacer.

13. The method of claim 11, wherein vertically recessing the horizontally-extending portion of the heater liner layer comprises performing an etch-back process that etches a material of the heater liner layer.

14. The method of claim 11, wherein a vertically-extending seam is formed within a vertically-extending portion of the heater liner layer that is deposited within the fraction of the volume of the via opening.

15. The method of claim 14, wherein:
the heater liner layer is formed with a planar horizontal surface segment that overlies the dielectric material layer, and an annular convex surface segment that is adjoined to a periphery of an opening in the planar horizontal surface segment and comprises a bottom tip point that adjoins a top end of the vertically-extending seam; and
vertically recessing the horizontally-extending portion of the heater liner layer comprises performing an etch-back process that vertically recesses the annular convex surface segment of the heater liner layer simultaneously while vertically recessing the horizontally-extending portion of the heater liner layer.

16. A device structure comprising:
a tubular dielectric spacer located within a via opening in a dielectric material layer;
a heater liner comprising a vertically-extending portion laterally surrounded by the tubular dielectric spacer and a horizontally-extending portion overlying a top surface segment of the dielectric material layer;
a phase change material portion comprising a phase change material contacting a top surface of the heater liner; and
a top electrode contacting a top surface of the phase change material portion.

17. The device structure of claim 16, wherein:
the heater liner comprises a planar horizontal surface segment that overlies the dielectric material layer and further comprises an annular convex surface segment that is adjoined to a periphery of an opening in the planar horizontal surface segment and overlies the via opening; and
the phase change material portion contacts the annular convex surface segment.

18. The device structure of claim 16, wherein:
the vertically-extending portion of the heater liner comprises a vertically-extending seam; and
a top surface of the heater liner comprises an annular convex surface segment having a bottom tip point that adjoins a top end of the vertically-extending seam.

19. The device structure of claim 16, wherein:
the phase change material portion comprises a vertically-extending portion located within a center region of the via opening; and
the vertically-extending portion of the heater liner comprises a cylindrical inner sidewall contacting the vertically-extending portion of the phase change material portion.

20. The device structure of claim 16, further comprising at least one sidewall liner located on at least one sidewall of the phase change material portion, contacting a sidewall of the horizontally-extending portion of the heater liner, and comprising a material having an electrical conductivity that is higher than an electrical conductivity of an amorphous phase of the phase change material.
